(19) United States
(12) Patent Application Publication
(10) Pub. No.: US 2026/0052668 A1
(43) Pub. Date: Feb. 19, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Jeon Il Lee, Suwon-si (KR); Dongkyun Lim, Suwon-si (KR)

(73) Assignee: Samsung Electronics Co., Ltd., Suwon-si (KR)

(21) Appl. No.: 19/044,367

(22) Filed: Feb. 3, 2025

(30) Foreign Application Priority Data
Aug. 14, 2024 (KR) 10-2024-0109326

(51) Int. Cl. H10B 12/00

(52) U.S. Cl. CPC H10B 12/09; H10B 12/30; H10B 12/50

(57) ABSTRACT

The present disclosure relates to a semiconductor device and a method of manufacturing the same. A method includes forming an intermediate structure including a plurality of first layers, and forming a plurality of cell semiconductor patterns by patterning a subset of the first layers such that an adjacent layer that is adjacent to a first surface of the substrate remain unpatterned. After flipping the intermediate structure on the substrate and attaching the intermediate structure on a lower insulating layer, the method includes patterning the adjacent layer to form a logic semiconductor pattern, forming a bit line connected to first ends of the plurality of cell semiconductor patterns, and forming a plurality of capacitors connected to second ends of the plurality of cell semiconductor patterns. The capacitors are disposed between the logic semiconductor pattern and the lower insulating layer.

### CROSS-REFERENCE TO RELATED APPLICATION

This application claims priority to and the benefit under 35 U.S.C. § 119(a)-(d) of Korean Patent Application No. 10-2024-0109326 filed at the Korean Intellectual Property Office on Aug. 14, 2024, the entire contents of which are incorporated herein by reference.

### BACKGROUND OF THE INVENTION

### (a) Field of the Invention

The present disclosure relates to a semiconductor device and a method of manufacturing the same.

### (b) Description of the Related Art

There is a demand for technology to increase the integration density of semiconductor devices. In the case of conventional two-dimensional semiconductor devices, since integration density may be mainly determined by the area occupied by a unit memory cell, the degree of integration density achieved may be influenced by the technology used to form fine patterns.

However, the very high cost of the equipment and techniques for forming increasingly finer patterns has become prohibitive. Accordingly, three-dimensional semiconductor memory devices having three-dimensionally arranged memory cells have been proposed.

### SUMMARY OF THE INVENTION

Embodiments provide a semiconductor device and a method of manufacturing the same in which circuit elements are arranged in an upper region of a plurality of capacitors among an upper region of a memory cell structure in which a plurality of memory cells are stacked. Embodiments of the present application may be used to implement dynamic random access memory (DRAM) devices, often used in computers and other electronic devices for temporary data storage.

A method of manufacturing a semiconductor device according to an embodiment includes forming an intermediate structure including a plurality of first layers, forming a plurality of cell semiconductor patterns by patterning a subset of the plurality of first layers such that an adjacent layer that is adjacent to a first surface of the substrate remains unpatterned, after flipping the intermediate structure on the substrate and attaching the intermediate structure on a lower insulating layer, patterning the adjacent layer to form a logic semiconductor pattern, forming a bit line connected to first ends of the plurality of cell semiconductor patterns, and forming a plurality of capacitors, connected to second ends of the plurality of cell semiconductor patterns, disposed between the logic semiconductor pattern and the lower insulating layer.

A method of manufacturing a semiconductor device according to an embodiment includes forming a first intermediate structure including a plurality of first layers, forming a logic semiconductor pattern by patterning a remote layer that is furthest from a first surface of the substrate among the plurality of first layers, after flipping the first intermediate structure on the substrate and attaching the first intermediate structure on an etch-stop layer, forming a second intermediate structure by forming a plurality of cell semiconductor patterns by patterning a subset of the plurality of first layers remaining layers, forming a bit line connected to first ends of the plurality of cell semiconductor patterns, forming a plurality of capacitors connected to the second ends of the plurality of cell semiconductor patterns, and attaching the second intermediate structure on a lower insulating layer, wherein the plurality of capacitors are disposed between the logic semiconductor pattern and the lower insulating layer.

A method of manufacturing a semiconductor device according to an embodiment includes forming an intermediate structure including a plurality of first layers, forming a plurality of cell semiconductor patterns by patterning a subset of the plurality of first layers such that an adjacent layer that is adjacent to a first surface of the substrate remains unpatterned, after flipping the intermediate structure on the substrate and attaching the intermediate structure on a lower insulating layer, patterning the adjacent layer to form a logic semiconductor pattern, forming a bit line connected to first ends of the plurality of cell semiconductor patterns along a first direction, and forming a plurality of capacitors, connected to second ends of the plurality of cell semiconductor patterns along the first direction, overlapping with the logic semiconductor pattern in a direction perpendicular to an upper surface of the lower insulating layer.

A semiconductor device according to an embodiment includes a lower insulating layer, a plurality of cell semiconductor patterns stacked in a direction perpendicular to an upper surface of the lower insulating layer, a bit line in contact with first ends of the plurality of cell semiconductor patterns in a first direction and extending in a direction perpendicular to an upper surface of the lower insulating layer, a plurality of capacitors in contact with second ends of the plurality of cell semiconductor patterns in the first direction, and a logic semiconductor pattern, wherein the plurality of capacitors are disposed between the logic semiconductor pattern and the lower insulating layer, the plurality of cell semiconductor patterns include a first cell semiconductor pattern and a second cell semiconductor pattern, the first cell semiconductor pattern is closer to an upper surface of a lower insulating layer than the second cell semiconductor pattern, and a width of the first cell semiconductor pattern in a second direction orthogonal to the first direction is shorter than a width of the second cell semiconductor pattern in the second direction.

According to embodiments, a semiconductor device may include a circuit element in an upper region of a plurality of capacitors among an upper region of a memory cell structure in which a plurality of memory cells are stacked, and reliability of the capacitors may be secured in a manufacturing process of the semiconductor device.

The manufacturing methods described herein result in more compact devices relative to conventional implementations. The inventors have recognized and appreciated that conventional memory devices are designed in a way that underutilizes the region of the device that is above the region in which the capacitors are formed. Recognizing this limitation, embodiments of the present application include logic transistors that are disposed in this region, thereby improving the real estate utilization.

### BRIEF DESCRIPTION OF THE DRAWINGS

FIG. 1 is a planar layout diagram of a semiconductor device according to an embodiment.

FIG. 2 is a cross-sectional view taken along line A-A′ of FIG. 1.

FIG. 3 is a cross-sectional view taken along line B-B′ of FIG. 1.

FIG. 4 is a cross-sectional view taken along line C-C′ of FIG. 1.

FIG. 5 is an enlarged view of R1 in FIG. 2.

FIG. 6 is a cross-sectional view of a semiconductor device according to an embodiment.

FIG. 7 is a cross-sectional view taken along line A-A′ of FIG. 1.

FIG. 8 is a cross-sectional view taken along line B-B′ of FIG. 1.

FIG. 9 is a cross-sectional view taken along line C-C′ of FIG. 1.

FIGS. 10 to 33 are drawings showing a method of manufacturing a semiconductor device according to an embodiment.

FIGS. 34 to 55 are drawings showing a method of manufacturing a semiconductor device according to an embodiment.

### DETAILED DESCRIPTION OF THE EMBODIMENTS

Hereinafter, the present disclosure will be described in detail with reference to the accompanying drawings, in which embodiments of the present disclosure are shown. As those skilled in the art would realize, the described embodiments may be modified in various different ways, all without departing from the spirit or scope of the present disclosure.

To concisely describe the disclosure, parts that are irrelevant to the description may be omitted, and like reference numerals and/or reference characters refer to like or similar constituent elements throughout the specification.

Further, since sizes and thicknesses of constituent members shown in the accompanying drawings may be arbitrarily given to facilitate understanding and ease of description, the disclosure is not limited to the shown sizes and thicknesses. In the drawings, the thickness of layers and regions are exaggerated for clarity. In the drawings, to facilitate understanding and ease of description, the thicknesses of some layers and areas may be exaggerated.

It should be understood that when an element such as a layer, film, region, or substrate is referred to as being “on” or “above” another element, it can be “directly on” the other element or intervening elements may also be present. In contrast, when an element is referred to as being “directly on” another element, there are no intervening elements present. Further, in the specification, the word “on” or “above” means disposed on or below the object portion, and does not necessarily mean that it is disposed on the upper side of the object portion based on a gravitational direction.

In addition, unless explicitly stated to the contrary, the word “comprise,” and variations such as “comprises” or “comprising,” should be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

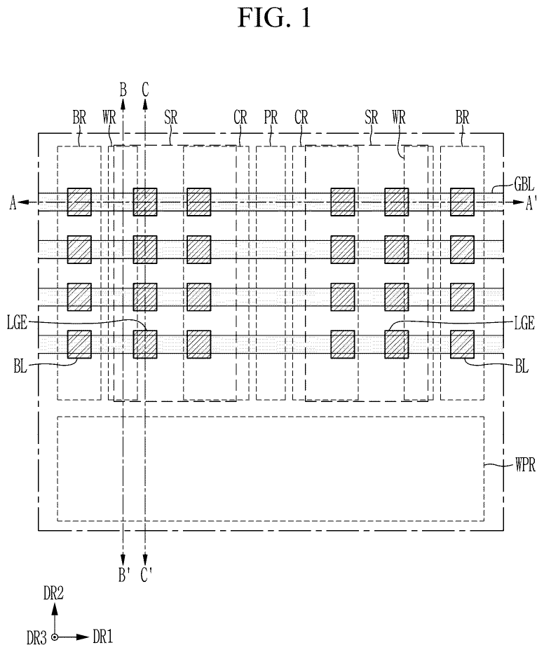

Hereinafter, a semiconductor device according to an embodiment will be described with reference to FIGS. 1 to 5.

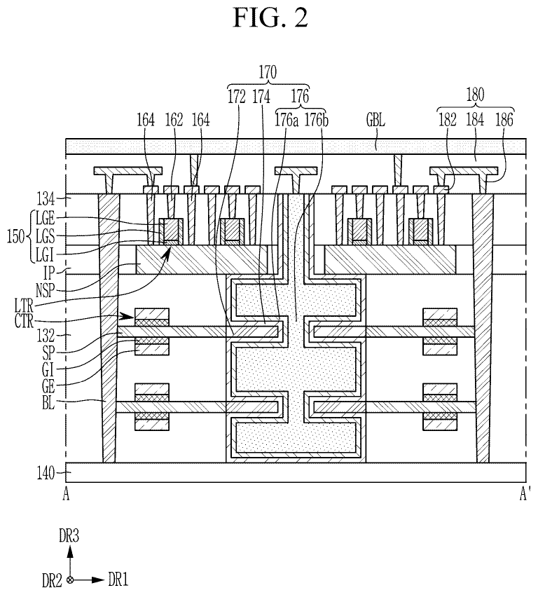

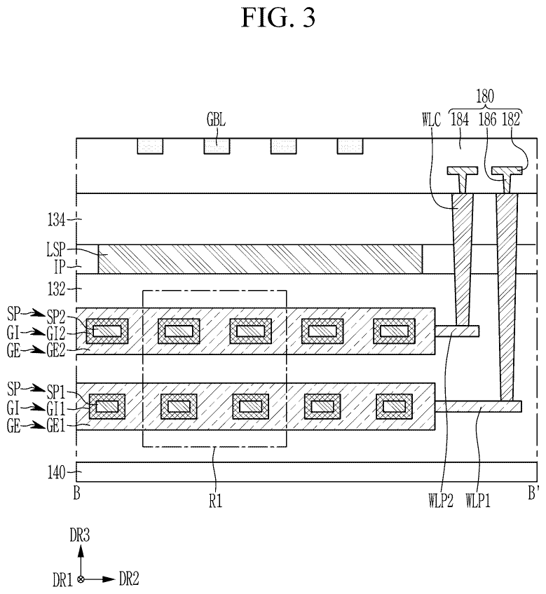

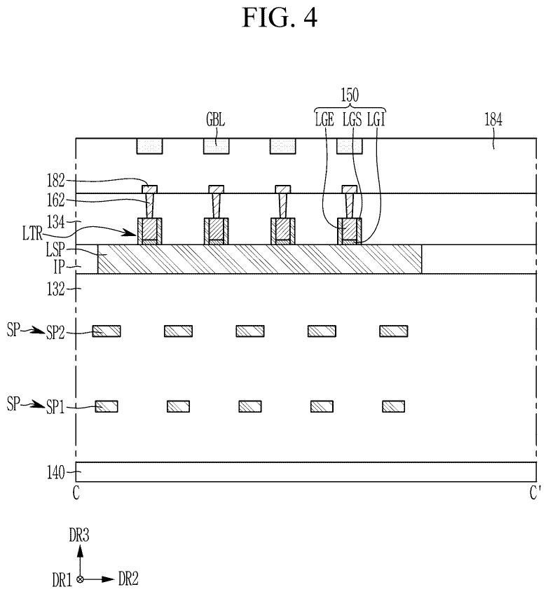

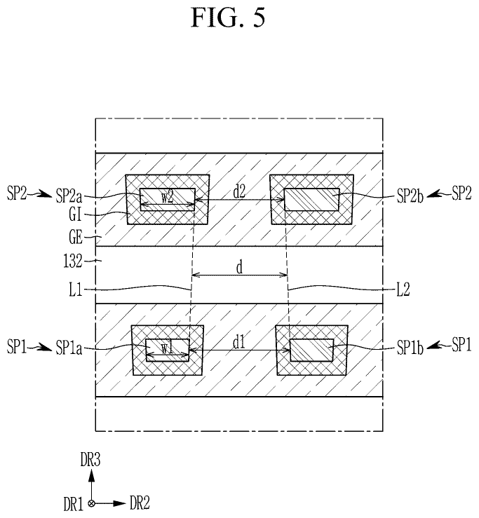

FIG. 1 is a planar layout diagram of a semiconductor device according to an embodiment. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. FIG. 5 is an enlarged view of R1 in FIG. 2.

Referring to FIGS. 1 to 4, a semiconductor device according to an embodiment may include a bit line region BR, a semiconductor region SR, a word line region WR, a capacitor region CR, a plate region PR, and a word line pad region WPR on a plane. The word line region WR may be disposed between the bit line region BR and the capacitor region CR. For example, the bit line region BR, the word line region WR, and the capacitor region CR may be disposed in a first direction DR1. A plate region PR may be disposed on one side of the capacitor region CR. At least a portion of the semiconductor region SR may overlap the capacitor region CR. The word line pad region WPR may be disposed on one side of the word line region WR. The word line pad region WPR and the word line region WR may be disposed in a second direction DR2. The second direction DR2 may be a direction intersecting the first direction DR1. For example, the second direction DR2 may be a direction perpendicular to the first direction DR1.

In FIG. 1, the word line pad region WPR is shown as being spaced apart from the word line region WR, but this is shown as being spaced apart to distinguish the regions, and the word line pad region WPR may actually be connected to the word line region WR.

A semiconductor device according to an embodiment may include a plurality of bit line regions BR, a plurality of semiconductor regions SR, a plurality of word line regions WR, and a plurality of capacitor regions CR. The plurality of bit line regions BR, the plurality of semiconductor regions SR, the plurality of word line regions WR, and the plurality of capacitor regions CR may be disposed symmetrically with respect to the plate region PR. Although a single plate region PR is illustrated in FIG. 1, the present disclosure is not limited thereto, and a semiconductor device according to an embodiment may include a plurality of plate regions PR, and the plurality of plate regions PR may be spaced apart in the first direction DR1. The bit line region BR, the semiconductor region SR, the word line region WR, and the capacitor region CR may be disposed on both sides of each of the plurality of plate regions PR, and may be disposed symmetrically with respect to each of the plurality of plate regions PR.

In FIG. 1, the capacitor region CR is shown as being spaced apart from the plate region PR, but this is shown to be spaced apart to distinguish the plurality of capacitor regions CR and the plate region PR, and the plate region PR may actually be connected to each of the capacitor regions CR disposed on both sides of the plate region PR.

Although FIG. 1 illustrates that the word line pad region WPR overlaps the bit line region BR and the capacitor region CR in the second direction DR2, this is only to indicate that the word line regions WR disposed on both sides of the plate region PR overlap in the second direction DR2, and the actual region of the word line pad region WPR may not overlap the bit line region BR and the capacitor region CR in the second direction DR2.

Although a single word line pad region WPR is illustrated in FIG. 1, the present disclosure is not limited thereto, and a semiconductor device according to an embodiment may include a plurality of word line pad regions WPR, and the plurality of word line pad regions WPR may be spaced apart in the first direction DR1. For example, each of the plurality of word line pad regions WPR may overlap the word line regions WR disposed on both sides of each of the plurality of plate regions PR in the second direction DR2.

A semiconductor device according to an embodiment may include a lower insulating layer 140, a plurality of cell semiconductor patterns SP, a plurality of cell gate electrodes GE, a bit line BL, a plurality of capacitors 170, an interlayer insulating layer 132, a logic semiconductor pattern LSP, and a logic gate electrode LGE.

The lower insulating layer 140 may include silicon oxide, silicon nitride, or silicon oxynitride, or a combination thereof. A plurality of cell semiconductor patterns SP may be stacked on the lower insulating layer 140. The plurality of cell semiconductor patterns SP may be spaced apart in a third direction DR3 perpendicular to the upper surface of the lower insulating layer 140.

The plurality of cell semiconductor patterns SP disposed on the same layer may be spaced apart from each other in the first direction DR1 and the second direction DR2. A capacitor 170 described later may be disposed between adjacent cell semiconductor patterns SP in the first direction DR1. A cell gate electrode GE may be disposed between the cell semiconductor patterns SP disposed in the second direction DR2.

In FIGS. 2 to 4, it is illustrated that there are two cell semiconductor patterns SP disposed in the first direction DR1 and five cell semiconductor patterns SP disposed in the second direction DR2, but this is not limited thereto, and the number of the cell semiconductor patterns SP disposed in the first direction DR1 and the second direction DR2 may be variously changed.

The cell semiconductor pattern SP may include a semiconductor material. For example, the cell semiconductor pattern SP may include silicon. A channel may be formed under the surface of the cell semiconductor pattern SP adjacent to the cell gate electrode GE. A semiconductor device according to an embodiment may have a gate all around (GAA) structure in which the cell gate electrode GE surrounds four surfaces of a channel.

The cell semiconductor pattern SP may have a bar shape extending in the first direction DR1. The cell semiconductor pattern SP may include one end and the other end facing each other in the first direction DR1. One end and the other end of the cell semiconductor pattern SP may correspond to a pair of source/drain regions. One end of the cell semiconductor pattern SP may be in contact with the bit line BL described later. The other end of the cell semiconductor pattern SP may be in contact with the capacitor 170 described later.

The cell gate electrode GE may surround a portion between one end and the other end of the cell semiconductor pattern SP. The cell gate electrode GE and the cell semiconductor pattern SP surrounded by the cell gate electrode GE may form a cell transistor CTR.

Each of the plurality of cell gate electrodes GE may surround each of the plurality of cell semiconductor patterns SP stacked in the third direction DR3. For example, the plurality of cell semiconductor patterns SP may include a first cell semiconductor pattern SP1 and a second cell semiconductor pattern SP2 that are stacked in the third direction DR3. For example, the plurality of cell gate electrodes GE may include a first cell gate electrode GE1 surrounding the first cell semiconductor pattern SP1 and a second cell gate electrode GE2 surrounding the second cell semiconductor pattern SP2.

In FIGS. 2 to 4, the number of the plurality of cell semiconductor patterns SP and the plurality of cell gate electrodes GE stacked in the third direction DR3 is illustrated as two, but is not limited thereto, and the number of the plurality of cell semiconductor patterns SP and the plurality of cell gate electrodes GE stacked in the third direction DR3 may be variously changed.

Each of a plurality of cell gate insulating layers GI may be disposed between each of the plurality of cell semiconductor patterns SP and each of the plurality of cell gate electrodes GE that are stacked in the third direction DR3. For example, the plurality of cell gate insulating layers GI may include a first cell gate insulating layer GI1 disposed between the first cell semiconductor pattern SP1 and the first cell gate electrode GE1, and a second cell gate insulating layer GI2 disposed between the second cell semiconductor pattern SP2 and the second cell gate electrode GE2.

Each of the plurality of cell gate electrodes GE may be separated from each of the plurality of cell semiconductor patterns SP by each of the plurality of cell gate insulating layers GI. The plurality of cell gate electrodes GE may be disposed in the word line region WR of FIG. 1. Each of the plurality of cell gate electrodes GE may have a line shape extending in the second direction DR2. Each of the plurality of cell gate electrodes GE may be referred to as a word line. Each of the plurality of cell gate electrodes GE may surround the cell semiconductor patterns SP disposed in the second direction DR2. In other words, the cell semiconductor patterns SP disposed in the second direction DR2 may share a single word line.

The cell gate electrode GE may include a conductive material. The conductive material may include, for example, a doped semiconductor material such as doped silicon or doped germanium, a conductive metal nitride such as titanium nitride or tantalum nitride, a metal such as tungsten, titanium, or tantalum, or a metal-semiconductor compound such as tungsten silicide, cobalt silicide, or titanium silicide.

The cell gate insulating layer GI may include at least one of a high dielectric layer, a silicon oxide layer, a silicon nitride layer, or a silicon oxynitride layer. The high dielectric layer may include, for example, at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The interlayer insulating layer 132 may be disposed between the plurality of cell semiconductor patterns SP stacked in the third direction DR3, between the plurality of cell gate insulating layers GI stacked in the third direction DR3, and between the plurality of cell gate electrodes GE stacked in the third direction DR3. The plurality of cell semiconductor patterns SP stacked in the third direction DR3 may be separated by the interlayer insulating layer 132. The plurality of cell gate insulating layers GI stacked in the third direction DR3 may be separated by the interlayer insulating layer 132. The plurality of cell gate electrodes GE stacked in the third direction DR3 may be separated by the interlayer insulating layer 132.

The interlayer insulating layer 132 may be disposed between the lower insulating layer 140 and the cell semiconductor pattern SP, between the lower insulating layer 140 and the cell gate insulating layer GI, and between the lower insulating layer 140 and the cell gate electrode GE.

The interlayer insulating layer 132 may include silicon oxide, silicon nitride, or silicon oxynitride, or a combination thereof.

An insulating pattern IP and a logic semiconductor pattern LSP may be disposed on the interlayer insulating layer 132. The logic semiconductor pattern LSP may be disposed in the semiconductor region SR of FIG. 1. A plurality of logic semiconductor patterns LSP may be disposed on the interlayer insulating layer 132. Each of the plurality of logic semiconductor patterns LSP may be defined by the insulating pattern IP. The insulating pattern IP may be disposed between the plurality of logic semiconductor patterns LSP. The plurality of logic semiconductor patterns LSP may be spaced apart from each other by the insulating pattern IP.

In an embodiment, the logic semiconductor pattern LSP may include the same semiconductor material as the cell semiconductor pattern SP. For example, the logic semiconductor pattern LSP may include monocrystalline silicon. The thickness of the logic semiconductor pattern LSP in the third direction DR3 may be thicker than the thickness of the cell semiconductor pattern SP in the third direction DR3.

A semiconductor device according to an embodiment may include a logic gate structure 150 disposed on the logic semiconductor pattern LSP. A plurality of logic gate structures 150 may be disposed on the logic semiconductor pattern LSP. For example, each of the plurality of logic gate structures 150 may include a logic gate electrode LGE, a logic gate spacer LGS covering both side surfaces of the logic gate electrode LGE, and a logic gate insulating layer LGI disposed between the logic gate electrode LGE and the logic semiconductor pattern LSP. The logic gate electrode LGE may be disposed within the semiconductor region SR of FIG. 1.

The logic gate electrode LGE may include a conductive material. The conductive material may include, for example, a doped semiconductor material such as doped silicon or doped germanium, a conductive metal nitride such as titanium nitride or tantalum nitride, a metal such as tungsten, titanium, or tantalum, or a metal-semiconductor compound such as tungsten silicide, cobalt silicide, or titanium silicide.

The logic gate spacer LGS may include at least one of a high dielectric layer, a silicon oxide layer, a silicon nitride layer, or a silicon oxynitride layer. The logic gate insulating layer LGI may include at least one of a high dielectric layer, a silicon oxide layer, a silicon nitride layer, or a silicon oxynitride layer. The high dielectric layer may include, for example, at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

A semiconductor device according to an embodiment may include an upper insulating layer 134 surrounding the logic gate structure 150. The upper insulating layer 134 may cover the upper surface of the insulating pattern IP and the plurality of logic semiconductor patterns LSP. The upper insulating layer 134 may cover the upper surface of the logic gate electrode LGE. The upper insulating layer 134 may cover the upper surface and side surfaces of the logic gate spacer LGS.

The upper insulating layer 134 may include silicon oxide, silicon nitride, or silicon oxynitride, or a combination thereof.

A pair of source/drain regions may be disposed on the logic semiconductor pattern LSP on both sides of the logic gate electrode LGE. The pair of source/drain regions may be disposed in the first direction DR1, and a channel may be formed between the pair of source/drain regions. The logic semiconductor pattern LSP including the pair of source/drain regions and the logic gate electrode LGE may form a logic transistor LTR.

A semiconductor device according to an embodiment may include a logic gate contact 162 penetrating the upper insulating layer 134 and contacting an upper surface of the logic gate electrode LGE, and a pair of source/drain contacts 164 penetrating the upper insulating layer 134 and contacting an upper surface of the logic semiconductor pattern LSP disposed on both sides of the logic gate electrode LGE. The logic gate contact 162 may be connected to the logic gate electrode LGE. The pair of source/drain contacts 164 may be respectively connected to the pair of source/drain regions.

The bit line BL may penetrate the upper insulating layer 134, the insulating pattern IP, and the interlayer insulating layer 132. The bit line BL may contact the upper surface of the lower insulating layer 140. The bit line BL may have a pillar shape extending in the third direction DR3 perpendicular to the upper surface of the lower insulating layer 140. The diameter of the bit line BL (for example, a width in the first direction DR1) may decrease as a distance from the upper surface of the lower insulating layer 140 decreases.

The bit line BL may be disposed in the bit line region BR of FIG. 1. In FIG. 1, the planar shape of the bit line BL is shown as being a quadrangle, but is not limited thereto and may be variously changed to a circle, an ellipse, or a polygon other than a quadrangle.

The bit line BL may contact one end of the cell semiconductor pattern SP. The bit line BL may contact one end of each of the plurality of cell semiconductor patterns SP stacked in the third direction DR3. The plurality of cell semiconductor patterns SP stacked in the third direction DR3 may share a single bit line BL.

The bit line BL may include a conductive material. The conductive material may include, for example, a doped semiconductor material such as doped silicon or doped germanium, a conductive metal nitride such as titanium nitride or tantalum nitride, a metal such as tungsten, titanium, or tantalum, or a metal-semiconductor compound such as tungsten silicide, cobalt silicide, or titanium silicide.

The capacitor 170 may be disposed in the capacitor region CR of FIG. 1. The capacitor 170 may contact the other end of the cell semiconductor pattern SP. The capacitor 170 may include a first electrode 172, a second electrode 176, and a dielectric layer 174 disposed between the first electrode 172 and the second electrode 176. One side surface of the first electrode 172 may contact the other end of the cell semiconductor pattern SP. The first electrode 172 may be connected to the cell semiconductor pattern SP in the first direction DR1. The length of the first electrode 172 in the second direction DR2 and the length of the first electrode 172 in the third direction DR3 may be the same as the cell semiconductor pattern SP.

The dielectric layer 174 may cover the remaining surfaces of the first electrode 172 except for the surface in contact with the cell semiconductor pattern SP. The dielectric layer 174 may cover the upper and lower surfaces of the first electrode 172 and may cover the side surface of the first electrode 172 facing the surface in contact with the cell semiconductor pattern SP. The dielectric layer 174 may cover the side surface of the interlayer insulating layer 132. The dielectric layer 174 may cover the upper surface of the lower insulating layer 140. The dielectric layer 174 may cover the lower surface of the logic semiconductor pattern LSP and the insulating pattern IP. The dielectric layer 174 may cover the side surface of the insulating pattern IP and the side surface of the upper insulating layer 134.

The second electrode 176 may include a first conductive layer 176a and a second conductive layer 176b. The first conductive layer 176a may be disposed on the dielectric layer 174. The first conductive layer 176a may cover the dielectric layer 174. The first conductive layer 176a may have a conformal shape along the surface profile of the dielectric layer 174. The second conductive layer 176b may be disposed on the first conductive layer 176a. The second conductive layer 176b may include vertical portions perpendicular to the upper surface of the lower insulating layer 140 and horizontal portions parallel to the upper surface of the lower insulating layer 140. The vertical portion of the second conductive layer 176b may be disposed in the plate region PR of FIG. 1. The vertical portion of the second conductive layer 176b may extend in the third direction DR3. The horizontal portions of the second conductive layer 176b may protrude in the first direction DR1 from the vertical portions of the second conductive layer 176b and be surrounded by the dielectric layer 174 and the first conductive layer 176a.

The first electrode 172 and the second electrode 176 may include a conductive material. Each of the first electrode 172 and the second electrode 176 may include at least one of a metal material such as titanium, tantalum, tungsten, copper, or aluminum, a conductive metal nitride such as titanium nitride or tantalum nitride, or a doped semiconductor material such as doped silicon or doped germanium. The first conductive layer 176a of the second electrode 176 may include the same material as the first electrode 172, and the second conductive layer 176b of the second electrode 176 may include a material different from the first conductive layer 176a and the first electrode 172. For example, the first conductive layer 176a of the first electrode 172 and the second electrode 176 may include titanium nitride, and the second conductive layer 176b of the second electrode 176 may include doped silicon germanium.

The dielectric layer 174 may include at least one of a dielectric material, a ferromagnetic material, or an antiferromagnetic material. The dielectric material may include a high dielectric constant material. For example, the dielectric material may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

A semiconductor device according to an embodiment may include the plurality of capacitors 170 each connected to the plurality of cell semiconductor patterns SP stacked in the third direction DR3. The plurality of capacitors 170 may include a plurality of first electrodes 172 each connected to the plurality of cell semiconductor patterns SP, and the dielectric layer 174 and the second electrode 176 commonly connected to the plurality of first electrodes 172. For example, the plurality of capacitors 170 may be stacked in the third direction DR3, and the plurality of capacitors 170 stacked in the third direction DR3 may be formed of the plurality of first electrodes 172, a single dielectric layer 174, and a single second electrode 176.

The plurality of capacitors 170 may be disposed between the lower insulating layer 140 and the logic semiconductor pattern LSP. The plurality of capacitors 170 may be disposed between the upper surface of the lower insulating layer 140 and the lower surface of the logic semiconductor pattern (LSP. The plurality of capacitors 170 may overlap the logic semiconductor pattern LSP in the third direction DR3. At least a portion of the semiconductor region SR on which the logic semiconductor pattern LSP is disposed on a plane of FIG. 1 may overlap the capacitor region CR on which the plurality of capacitors 170 are disposed.

Meanwhile, each of the plurality of capacitors 170 is connected to the cell semiconductor pattern SP, and thus may be referred to as a cell capacitor. The cell transistor CTR and the cell capacitor may form one memory cell. A semiconductor device according to an embodiment may include a plurality of memory cells, and the plurality of memory cells may be stacked in the third direction DR3 perpendicular to an upper surface of the lower insulating layer 140 and may be spaced apart from each other in the first direction DR1 and the second direction DR2 in the same layer. According to an embodiment, two memory cells adjacent in the first direction DR1 may share the dielectric layer 174 and the second electrode 176. Two memory cells adjacent in the first direction DR1 may have a symmetrical structure based on the vertical portion of the second conductive layer 176b.

In FIG. 2, only a pair of memory cells having a symmetrical structure and being adjacent in the first direction DR1 are illustrated, but it is not limited thereto, and a plurality of pairs of memory cells having a symmetrical structure may be further disposed while being spaced apart in the first direction DR1.

In addition, although FIGS. 2 to 5 illustrate that two memory cells are stacked in the third direction DR3 and five memory cells are disposed in the second direction DR2, it is not limited thereto, and the number of memory cells stacked in the third direction DR3 and the number of memory cells disposed in the second direction DR2 may be variously changed.

A semiconductor device according to an embodiment may include a cell gate connection pad WLP connected to the cell gate electrode GE and a cell gate contact WLC connected to the cell gate connection pad WLP. The cell gate connection pad WLP and the cell gate contact WLC may be disposed in the word line pad region WPR of FIG. 1.

The cell gate connection pad WLP may extend from an end of the cell gate electrode GE in the second direction DR2 in which the cell gate electrode GE extends. The cell gate connection pad WLP may include the same material as the cell gate electrode GE. Accordingly, the interface between the cell gate electrode GE and the cell gate connection pad WLP may not be identified. The thickness of the cell gate connection pad WLP may be thinner than the cell gate electrode GE. For example, the thickness of the cell gate connection pad WLP may be substantially the same as the thickness of the cell semiconductor pattern SP. The thickness of the cell gate connection pad WLP may refer to the length in the third direction DR3. The cell gate connection pad WLP may have a shape protruding in the second direction DR2 from an end of the cell gate electrode GE.

The semiconductor device may include a plurality of cell gate connection pads WLP each connected to the plurality of cell gate electrodes GE. For example, the plurality of cell gate connection pads WLP may include a first cell gate connection pad WLP1 connected to the first cell gate electrode GE1 and a second cell gate connection pad WLP2 connected to the second cell gate electrode GE2. The length of each of the plurality of cell gate connection pads WLP in the second direction DR2 may become longer as a distance from the upper surface of the lower insulating layer 140 decreases. For example, the first cell gate connection pad WLP1 may be closer to the upper surface of the lower insulating layer 140 than the second cell gate connection pad WLP2. The length of the first cell gate connection pad WLP1 in the second direction DR2 may be longer than the length of the second cell gate connection pad WLP2 in the second direction DR2. The plurality of cell gate connection pads WLP may have a stepped structure that increases in height as the plurality of cell gate connection pads WLP move away from the upper surface of the lower insulating layer 140.

The cell gate contact WLC may penetrate the upper insulating layer 134, the insulating pattern IP, and the interlayer insulating layer 132 to contact the upper surface of the cell gate connection pad WLP. The cell gate contact WLC may have a pillar shape extending in the third direction DR3 perpendicular to the upper surface of the cell gate connection pad WLP. The diameter (for example, a width in the second direction DR2) of the cell gate contact WLC may decrease as a distance from the upper surface of the cell gate connection pad WLP decreases.

The semiconductor device may include the plurality of cell gate contacts WLC, each connected to the plurality of cell gate connection pads WLP. As described above, since the plurality of cell gate connection pads WLP have a stepped structure, at least a portion of the upper surface of each of the plurality of cell gate connection pads WLP may be exposed in an upward direction. The plurality of cell gate contacts WLC may be respectively connected to the exposed upper surfaces of the plurality of cell gate connection pads WLP.

A semiconductor device according to an embodiment may include a wiring layer 180 and a global bit line GBL disposed on the upper insulating layer 134. The wiring layer 180 may include a plurality of wirings 182 forming a plurality of layers, a wiring insulating layer 184 disposed between the plurality of wirings 182, and a plurality of vias 186 connecting the plurality of wirings 182 disposed in different layers.

The plurality of wirings 182 and the plurality of vias 186 may include a conductive material. The conductive material may include a metal such as copper, aluminum, or tungsten. The wiring insulating layer 184 may include an insulating material such as silicon oxide, silicon nitride, or silicon oxynitride.

The global bit line GBL may extend in a direction parallel to the upper surface of the upper insulating layer 134 (for example, in the second direction DR2). The global bit line GBL may be disposed on the wiring insulating layer 184. The lower surface and both side surfaces of the global bit line GBL may be covered with the wiring insulating layer 184, but is not limited thereto, and the wiring insulating layer 184 may further cover the upper surface of the global bit line GBL. The global bit line GBL may be included in any one of the plurality of layers formed by the plurality of wirings 182. That is, some of the plurality of wirings 182 may be disposed on the same layer as the global bit line GBL, and some of the plurality of wirings 182 may be disposed on the global bit line GBL.

The global bit line GBL may include a conductive material. The conductive material may include, for example, a doped semiconductor material such as doped silicon or doped germanium, a conductive metal nitride such as titanium nitride or tantalum nitride, a metal such as tungsten, titanium, or tantalum, or a metal-semiconductor compound such as tungsten silicide, cobalt silicide, or titanium silicide.

The wiring layer 180 may connect the global bit line GBL and the bit line BL. The bit line BL directly connected to a memory cell may be referred to as a local bit line. The global bit line GBL may be connected to the plurality of local bit lines.

In an embodiment, the logic transistor LTR may be connected between the global bit line GBL and the bit line BL. The logic transistor LTR may include a first source/drain region and a second source/drain region. The first source/drain region and the second source/drain region may correspond to regions of the logic semiconductor pattern LSP on both sides of the logic gate electrode LGE. The first source/drain region of the logic transistor LTR may be connected to the bit line BL, and the second source/drain region of the logic transistor LTR may be connected to the global bit line GBL. As described above, a pair of source/drain contacts 164 may be respectively connected to a pair of source/drain regions of the logic transistor LTR. That is, one of the pair of source/drain contacts 164 may be connected to the first source/drain region, and the other of the pair of source/drain contacts 164 may be connected to the second source/drain region. According to an embodiment, the wiring layer 180 may connect the source/drain contact 164 connected to the first source/drain region of the logic transistor LTR and the bit line BL, and may connect the source/drain contact 164 connected to the second source/drain region of the logic transistor LTR and the global bit line GBL.

According to an embodiment, at least one logic transistor LTR may be connected between the global bit line GBL and the plurality of bit lines BL. At least one logic transistor LTR connected between the global bit line GBL and the plurality of bit lines BL may serve to select some of the plurality of bit lines BL. In an embodiment, at least one logic transistor LTR connected between the global bit line GBL and the plurality of bit lines BL may form a multiplexer circuit.

However, the embodiment is not limited to the logic transistor LTR being a transistor of a multiplexer circuit. The logic transistors LTR may be a variety of transistors configuring core circuits and peripheral circuits that control memory cells. For example, the logic transistor LTR may be a transistor of a circuit that senses and amplifies data from the bit line BL (sense amplifier), or a transistor of a circuit that selects the cell gate electrode GE by applying a voltage to the cell gate electrode GE (sub-wordline driver).

The wiring layer 180 may be connected to the second electrode 176 of the capacitor 170. For example, the wiring layer 180 may connect the second electrode 176 of the capacitor 170 and the logic transistor, and the logic transistor LTR connected to the second electrode 176 may serve to control the second electrode 176.

The wiring layer 180 may be connected to the cell gate contact WLC. For example, the wiring layer 180 may connect the cell gate contact WLC to a power line that applies voltage to the cell gate electrode GE. Accordingly, voltage may be applied to the cell gate electrode GE through the wiring layer 180, the cell gate contact WLC, and the cell gate connection pad WLP.

Hereinafter, with further reference to FIG. 5, the width in the second direction DR2 of the plurality of cell semiconductor patterns SP stacked in the third direction DR3 of a semiconductor device according to an embodiment will be described.

As described above, the plurality of cell semiconductor patterns SP may include the first cell semiconductor pattern SP1 and the second cell semiconductor pattern SP2 that are stacked in the third direction DR3. The first cell semiconductor pattern SP1 may be closer to the upper surface of the lower insulating layer 140 than the second cell semiconductor pattern SP2. According to an embodiment, the plurality of cell semiconductor patterns SP stacked in the third direction DR3 may have a width in the second direction DR2 that becomes shorter as a distance from the upper surface of the lower insulating layer 140 decreases. Referring to FIG. 5, a width w1 of the first cell semiconductor pattern SP1 in the second direction DR2 may be shorter than a width w2 of the second cell semiconductor pattern SP2 in the second direction DR2. The second direction DR2 may be the direction in which the cell gate electrode GE extends. For example, an opening penetrating a plurality of cell semiconductor layers may be formed, and an insulating material may be filled into the opening to form the plurality of cell semiconductor patterns. In this case, the opening may narrow as it becomes closer to the substrate. Here, the width of the opening may correspond to the spacing between the cell semiconductor patterns located in the same layer. When the spacing between the cell semiconductor patterns increases, the width of each cell semiconductor pattern may decrease. Subsequently, the structure on the substrate may be flipped and attached to the lower insulating layer 140. Accordingly, the width of the first cell semiconductor pattern SP1 in the second direction, which is relatively closer to the lower insulating layer 140 among the first cell semiconductor pattern SP1 and second cell semiconductor pattern SP2, may be smaller than the width of the second cell semiconductor pattern SP2 in the second direction.

The plurality of cell semiconductor patterns SP may include first cell semiconductor patterns SP1a and SP1b adjacent in the second direction DR2 and second cell semiconductor patterns SP2a and SP2b adjacent in the second direction DR2. A gap d1 between the facing side surfaces of the adjacent first cell semiconductor patterns SP1a and SP1b in the second direction DR2 may be greater than a gap d2 between the facing side surfaces of the adjacent second cell semiconductor patterns SP2a and SP2b in the second direction DR2.

The facing side surfaces of the adjacent first cell semiconductor patterns SP1a and SP1b and the facing side surfaces of the adjacent second cell semiconductor patterns SP2a and SP2b may form a first extension line L1 and a second extension line L2 approximately in the third direction DR3. According to an embodiment, a width d between the first extension line L1 and the second extension line L2 may increase as a distance from the upper surface of the lower insulating layer 140 decreases.

The plurality of capacitors 170 of a semiconductor device according to an embodiment may be disposed between the lower insulating layer 140 and the logic semiconductor pattern LSP. In other words, the capacitor region CR where the plurality of capacitors 170 are disposed and the semiconductor region SR where the logic transistors LTR are disposed may overlap on a plane. The logic transistor LTR may be disposed in the upper region of the plurality of capacitors 170.

For example, in order to form the logic transistor LTR in the upper region of the plurality of capacitors 170, the plurality of capacitors 170 may be formed first, and the logic transistor LTR may be formed later in the upper region of the plurality of capacitors 170. In this case, the plurality of capacitors 170 may not operate properly due to heat applied to the plurality of capacitors 170 during the process of forming the logic transistor LTR.

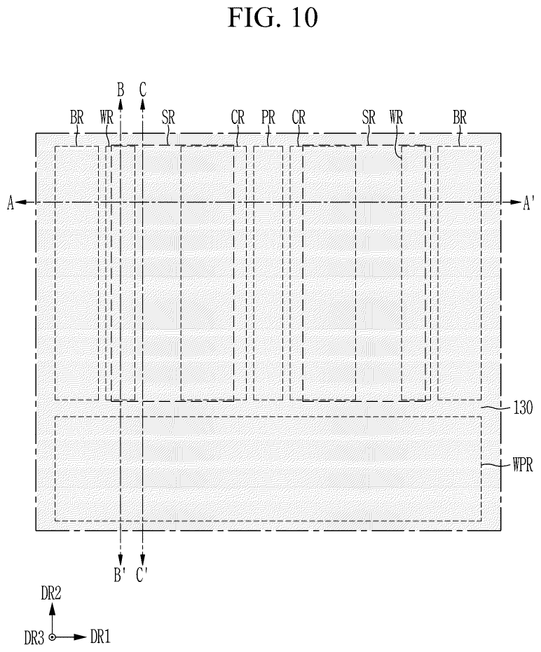

The semiconductor device according to an embodiment may first form the logic transistor LTR and then form the plurality of capacitors 170 later, according to a manufacturing method described later with reference to FIGS. 10 to 33. Accordingly, the logic transistor LTR may be formed in the upper region of the plurality of capacitors 170 while ensuring the reliability of the plurality of capacitors 170. According to an embodiment, unlike a comparative example where circuit elements could not be formed in the upper region of the plurality of capacitors 170 among the upper regions of the memory cell structure in which the plurality of memory cells are stacked, the upper region of the plurality of capacitors 170 may be further utilized.

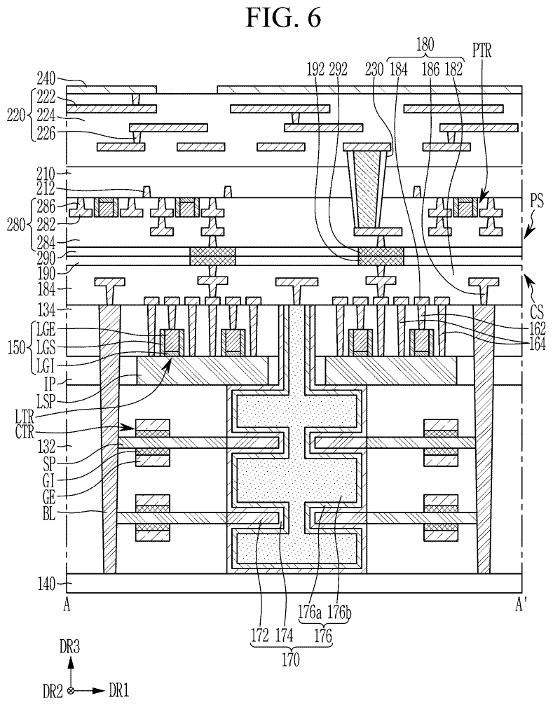

Hereinafter, a modified example of a semiconductor device according to one embodiment will be described with reference to FIG. 6.

FIG. 6 is a cross-sectional view of a semiconductor device according to an embodiment. For the semiconductor device illustrated in FIG. 6, any description overlapping that of the semiconductor device illustrated in FIGS. 1 to 5 will be omitted, and the differences will be briefly described.

Referring to FIG. 6, a semiconductor device according to an embodiment may have a peripheral circuit structure PS disposed on a memory cell structure CS. The memory cell structure CS may include components of the semiconductor devices illustrated in FIGS. 1 to 5. According to an embodiment, a first bonding insulating layer 190 and a plurality of first bonding pads 192 may be disposed on the wiring layer 180. The first bonding insulating layer 190 may be disposed between the plurality of first bonding pads 192. The first bonding insulating layer 190 may insulate the plurality of first bonding pads 192 from each other. The plurality of first bonding pads 192 may be connected to the wiring layer 180. The wiring layer 180 may be connected to the logic transistor LTR and the cell transistor CTR. For example, the wiring layer 180 may be connected to the logic gate contact 162 and the pair of source/drain contacts 164 of the logic transistor LTR. The wiring layer 180 may be connected to the bit line BL connected to the cell transistor CTR. Although not shown in FIG. 6, the wiring layer 180 may be connected to the cell gate contact WLC connected to the cell gate electrode GE of the cell transistor CTR. In FIG. 6, the illustration of the global bit line GBL is omitted, but the wiring layer 180 may also be connected to the global bit line GBL.

The peripheral circuit structure PS may include a substrate 210, a peripheral circuit transistor PTR and a peripheral circuit wiring layer 280 disposed on a first surface of the substrate 210, a redistribution layer 220 disposed on a second surface of the substrate 210 facing the first surface, a through via 230 connecting the redistribution layer 220 and the peripheral circuit wiring layer 280, a second bonding insulating layer 290 and a plurality of second bonding pads 292 disposed on the peripheral circuit wiring layer 280, and an external connection pad 240 disposed on the redistribution layer 220.

The substrate 210 may include a semiconductor material. For example, the substrate 210 may include silicon and/or silicon germanium. For example, the substrate 210 may include a base layer including silicon germanium and an epitaxial layer disposed on the base layer and including silicon.

A device isolation pattern 212 may be disposed in the substrate 210. The device isolation pattern 212 may be embedded in the first surface of the substrate 210. The peripheral circuit transistor PTR may be disposed on an active region of the substrate 210 defined by the device isolation pattern 212.

The peripheral circuit wiring layer 280 disposed on the substrate 210 may be connected to the peripheral circuit transistor PTR. The peripheral circuit wiring layer 280 may include a plurality of wirings 282 forming a plurality of layers, a wiring insulating layer 284 disposed between the plurality of wirings 282, and a plurality of vias 286 connecting the plurality of wirings 282 disposed in different layers. Some of the plurality vias 286 may include a pair of source/drain contacts and a gate contact of the peripheral circuit transistor PTR. The peripheral circuit wiring layer 280 may be connected to the source/drain regions and the gate electrode of the peripheral circuit transistor PTR.

The second bonding insulating layer 290 and the plurality of second bonding pads 292 may be disposed on the peripheral circuit wiring layer 280. The second bonding insulating layer 290 may be disposed between the plurality of second bonding pads 292. The second bonding insulating layer 290 may insulate the plurality of second bonding pads 292 from each other. The plurality of second bonding pads 292 may be connected to the peripheral circuit wiring layer 280.

The redistribution layer 220 may be disposed on the second surface of the substrate 210. The redistribution layer 220 may include a plurality of redistribution lines 222 forming a plurality of layers, a redistribution insulating layer 224 disposed between the plurality of redistribution lines 222, and a plurality of redistribution vias 226 connecting the plurality of redistribution lines 222 disposed in different layers.

The redistribution layer 220 may be connected to the peripheral circuit wiring layer 280. The redistribution layer 220 may be connected to the peripheral circuit wiring layer 280 by the through via 230. The through via 230 may penetrate the redistribution insulating layer 224, the substrate 210, and the wiring insulating layer 284. The lower surface of the through via 230 may be in contact with the wiring 282 of the peripheral circuit wiring layer 280, and the upper surface of the through via 230 may be in contact with the redistribution line 222.

The through via 230 may have a pillar shape extending in the third direction DR3 perpendicular to the first and second surfaces of the substrate 210. The through via 230 may include a conductive via and an insulating spacer surrounding the sidewall of the conductive via.

The external connection pad 240 may be disposed on the redistribution layer 220. The redistribution layer 220 may be connected to the external connection pad 240.

According to an embodiment, the memory cell structure CS and the peripheral circuit structure PS may be bonded in a hybrid bonding manner. The first bonding pad 192) of the memory cell structure CS and the second bonding pad 292 of the peripheral circuit structure PS may be bonded, and the first bonding insulating layer 190 of the memory cell structure CS and the second bonding insulating layer 290 of the peripheral circuit structure PS may be bonded. For example, the first bonding pad 192 and the second bonding pad 292 may include a metal material such as copper. The first bonding insulating layer 190 and the second bonding insulating layer 290 may include an insulating material such as silicon oxide. That is, a bond between metal materials and a bond between insulating materials may be formed at a bonding surface. According to an embodiment, the first bonding pad 192 of the memory cell structure CS and the second bonding pad 292 of the peripheral circuit structure PS may be directly bonded without bumps.

As described above, the memory cell structure CS and the peripheral circuit structure PS may be formed on different wafers respectively and then electrically connected by inter-wafer bonding. According to the comparative example, the memory cell structure CS may include the cell transistor CTR, and the peripheral circuit structure PS may include all peripheral circuit transistors PTR. In this case, the size of the peripheral circuit structure PS may increase and the routing may become complex.

According to an embodiment, the memory cell structure CS may include the cell transistor CTR and the logic transistor LTR disposed in an upper region of the plurality of capacitors 170. The logic transistor LTR included in the memory cell structure CS may correspond to a part of the peripheral circuit transistor PTR. For example, the logic transistor LTR of the memory cell structure CS may implement a circuit for selecting the bit line BL or a circuit for controlling the second electrode 176 of the capacitor 170. The core circuit and peripheral circuits controlling other memory cells may be implemented by peripheral circuit transistors PTR of the peripheral circuit structure PS. As another example, the logic transistor LTR of the memory cell structure CS may further implement a circuit that senses and amplifies data from the bit line BL. According to an embodiment, it is possible to reduce the size of the peripheral circuit structure PS and lower the routing complexity by replacing at least some of the peripheral circuit transistors PTR with the logic transistors LTR disposed in the upper region of the plurality of capacitors 170 of the memory cell structure CS.

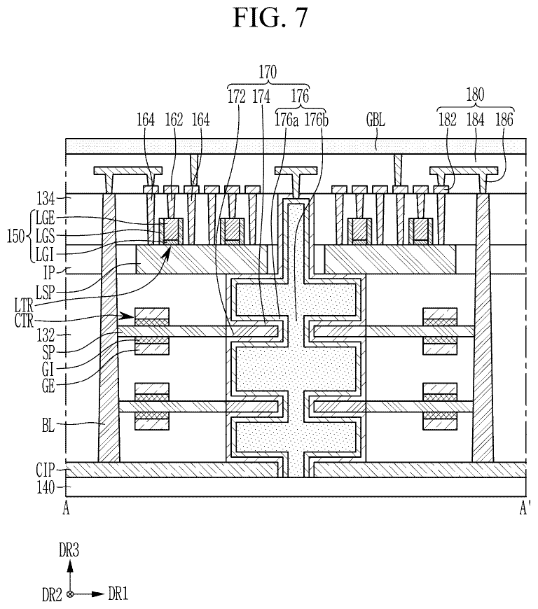

Hereinafter, a modified example of a semiconductor device according to an embodiment will be described with reference to FIGS. 7 to 9. The semiconductor devices illustrated in FIGS. 7 to 9 may have the same planar layout diagram as FIG. 1.

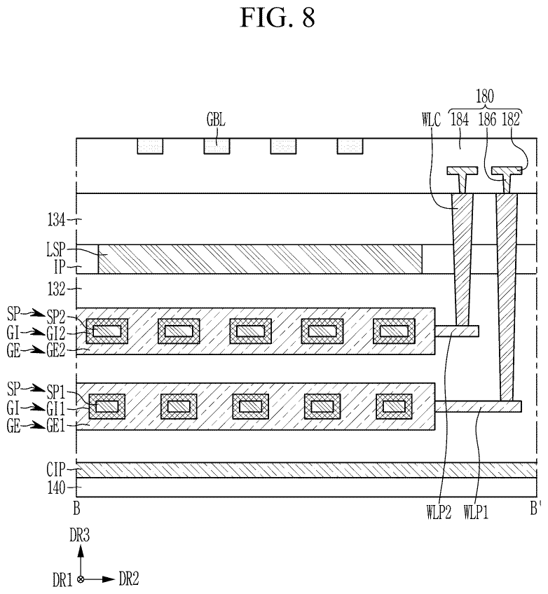

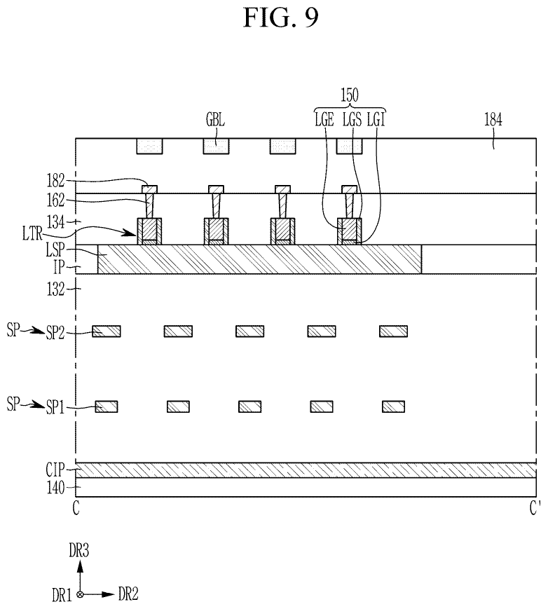

FIG. 7 is a cross-sectional view taken along line A-A′ of FIG. 1. FIG. 8 is a cross-sectional view taken along line B-B′ of FIG. 1. FIG. 9 is a cross-sectional view taken along line C-C′ of FIG. 1. For the semiconductor devices illustrated in FIGS. 7 to 9, any description overlapping that of the semiconductor devices illustrated in FIGS. 1 to 5 will be omitted, and the differences will be briefly described.

The semiconductor devices illustrated in FIGS. 7 to 9 differ from the semiconductor devices illustrated in FIGS. 1 to 5 in that a cover insulating pattern CIP is added between the lower insulating layer 140 and the interlayer insulating layer 132, and some of the structures of the bit line BL and the capacitor 170 are different.

Specifically, referring to FIGS. 7 to 9, a semiconductor device according to an embodiment may include the cover insulating pattern CIP disposed between the lower insulating layer 140 and the interlayer insulating layer 132. The cover insulating pattern CIP may be disposed between the bit line BL and the lower insulating layer 140, between the interlayer insulating layer 132 and the lower insulating layer 140, and between the plurality of capacitors 170 and the lower insulating layer 140. The cover insulating pattern may include an opening OP. The dielectric layer 174 and the second electrode 176 may be disposed inside the opening OP. The second electrode 176 may be surrounded by the dielectric layer 174. The dielectric layer 174 and the first conductive layer 176a of the second electrode 176 sequentially cover the inner surface of the opening OP, and the remaining space of the opening OP may be filled with the second conductive layer 176b of the second electrode 176.

As described above with reference to FIGS. 1 to 5, the second conductive layer 176b may include a vertical portion perpendicular to the upper surface of the lower insulating layer 140 and a horizontal portion parallel to the upper surface of the lower insulating layer 140. The vertical portion may extend in the third direction DR3, and the horizontal portion may protrude from the vertical portion in the first direction DR1. According to the embodiments illustrated in FIGS. 7 to 9, the vertical portion of the second conductive layer 176b may penetrate the opening OP in the third direction DR3, and the first conductive layer 176a and the dielectric layer 174 may surround the vertical portion of the second conductive layer 176b in the opening OP.

In the embodiments illustrated in FIGS. 1 to 5, the dielectric layer 174 is in contact with the upper surface of the lower insulating layer 140, and the second electrode 176 may be separated from the lower insulating layer 140 by the dielectric layer 174. On the other hand, in the embodiments illustrated in FIGS. 7 to 9, the dielectric layer 174 and the second electrode 176 may be in contact with the upper surface of the lower insulating layer 140. The first conductive layer 176a and the second conductive layer 176b of the second electrode 176 may contact the upper surface of the lower insulating layer 140.

According to the embodiments illustrated in FIGS. 7 to 9, the shape and structure of the first electrode 172 are the same as those of the semiconductor devices illustrated in FIGS. 1 to 5, but some of the structures of the dielectric layer 174 surrounded by the upper insulating layer 134 and the second electrode 176 are different. In the embodiments illustrated in FIGS. 1 to 5, the top surface of the second conductive layer 176b and the top surface of the first conductive layer 176a may not be covered by the dielectric layer 174, but may be covered by the wiring insulating layer 184. In other words, the second electrode 176 may contact the wiring insulating layer 184. The top surface of the second conductive layer 176b, the top surface of the first conductive layer 176a, and the top surface of the dielectric layer 174 may be disposed at substantially the same level as the upper surface of the upper insulating layer 134. The top surface may refer to as the surface furthest from the lower insulating layer 140.

On the other hand, in the embodiments illustrated in FIGS. 7 to 9, the top surface of the second conductive layer 176b may be covered with the first conductive layer 176a. The top surface of the first conductive layer 176a may be covered with the dielectric layer 174. That is, the second electrode 176 may be separated from the wiring insulating layer 184 by the dielectric layer 174. The top surface of the second conductive layer 176b and the top surface of the first conductive layer 176a may be disposed at a level lower than the upper surface of the upper insulating layer 134, and the top surface of the dielectric layer 174 may be disposed at substantially the same level as the upper surface of the upper insulating layer 134.

According to the embodiments illustrated in FIGS. 7 to 9, among the plurality of vias 186 of the wiring layer 180, the via 186 connected to the second electrode 176 may penetrate the dielectric layer 174 and contact the upper surface of the second electrode 176. In the embodiments illustrated in FIGS. 1 to 5, the via 186 connected to the second electrode 176 may contact the upper surface of the second conductive layer 176b. On the other hand, in the embodiments illustrated in FIGS. 7 to 9, the via 186 connected to the second electrode 176 may contact the upper surface of the first conductive layer 176a, but is not necessarily limited thereto. For example, the via 186 connected to the second electrode 176 may further penetrate the first conductive layer 176a and contact the upper surface of the second conductive layer 176b.

According to the embodiments illustrated in FIGS. 7 to 9, the bit lines BL have the same pillar shape extending in the third direction DR3 perpendicular to the upper surface of the lower insulating layer 140, but the direction in which the diameter of the bit lines BL (for example, a width in the first direction DR1) decreases may be different. In the embodiments illustrated in FIGS. 1 to 5, the diameter of the bit line BL (for example, a width in the first direction DR1) may decrease as a distance from the upper surface of the lower insulating layer 140 decreases. On the other hand, in the embodiments illustrated in FIGS. 7 to 9, the diameter of the bit line BL (for example, a width in the first direction DR1) may decrease as a distance from the upper surface of the lower insulating layer 140 increases.

In addition to the above-described contents, the description of the embodiments of FIGS. 1 to 5 may be applied identically or similarly to other components.

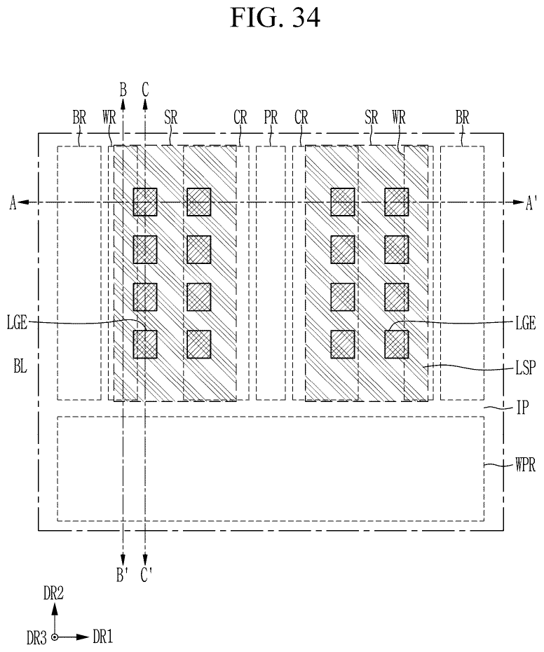

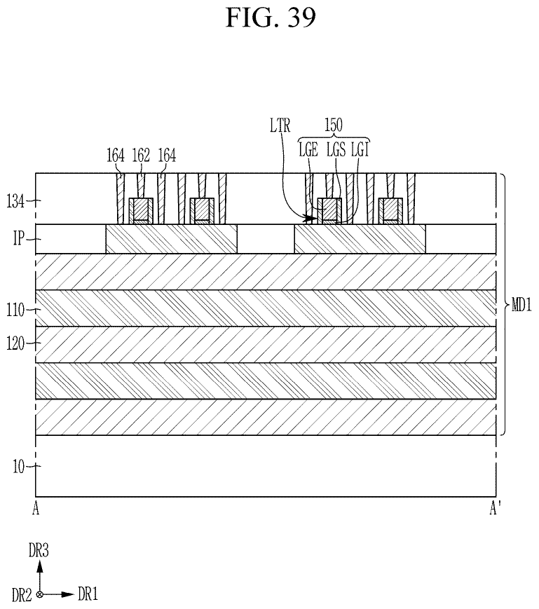

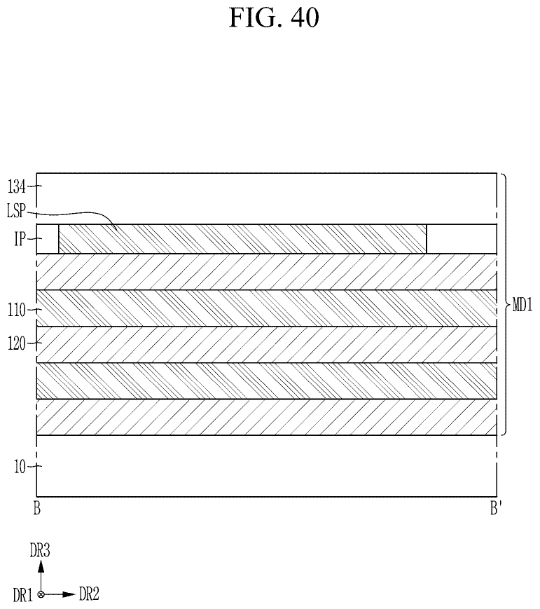

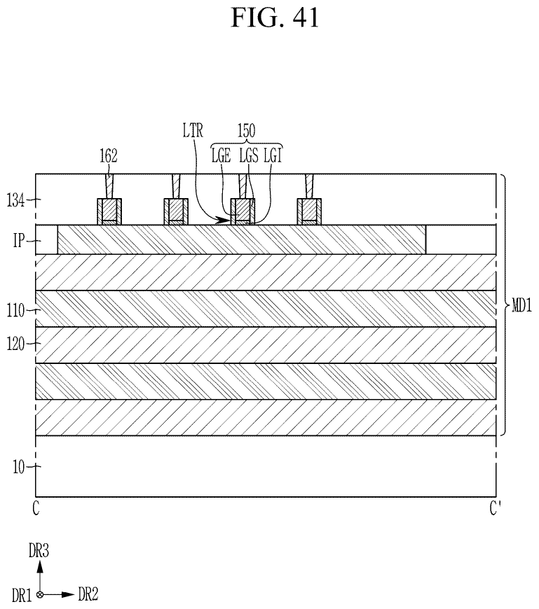

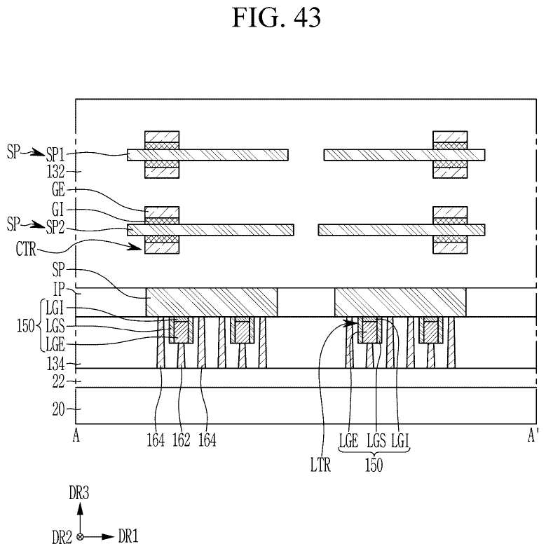

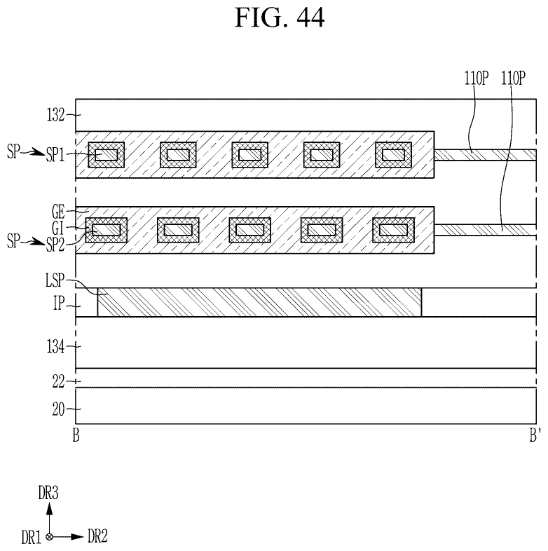

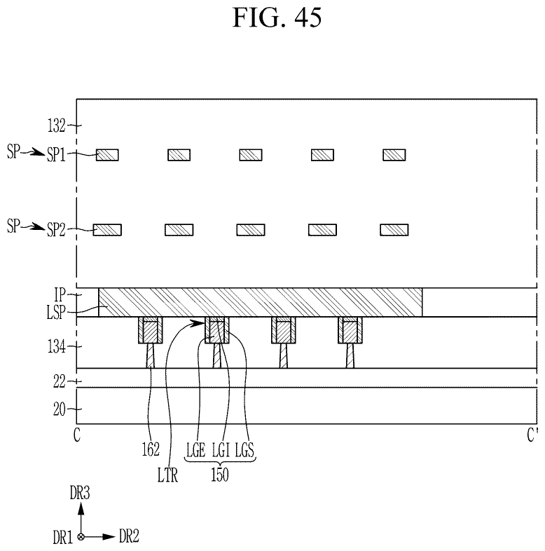

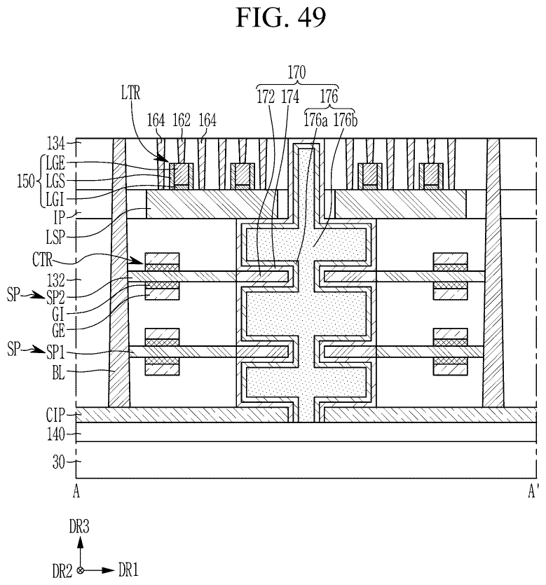

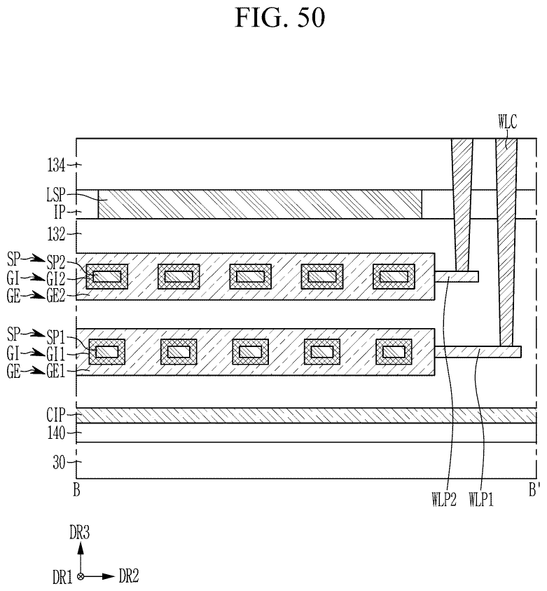

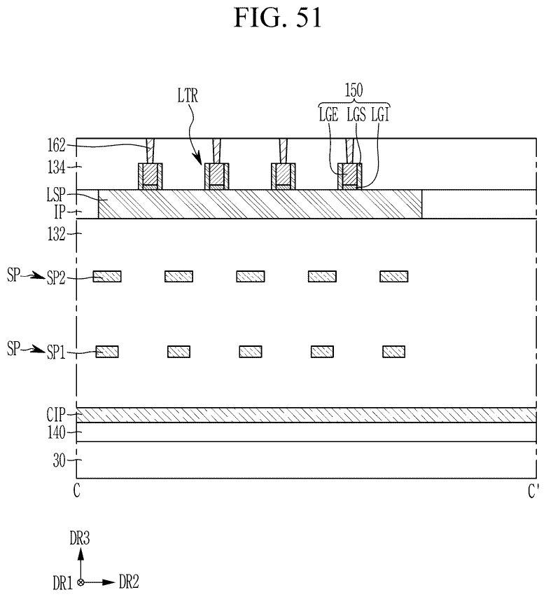

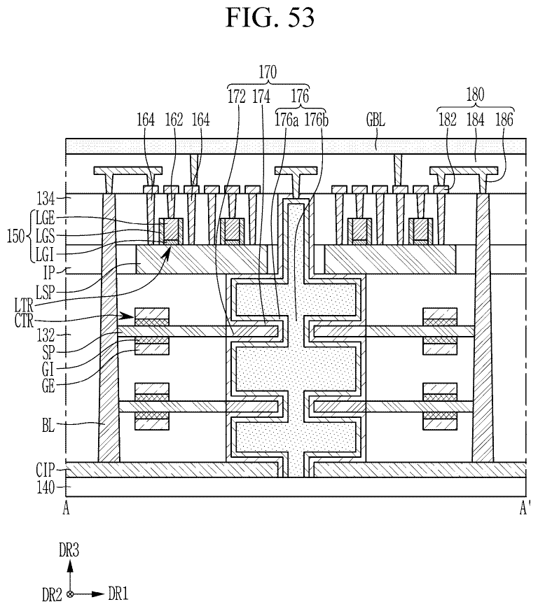

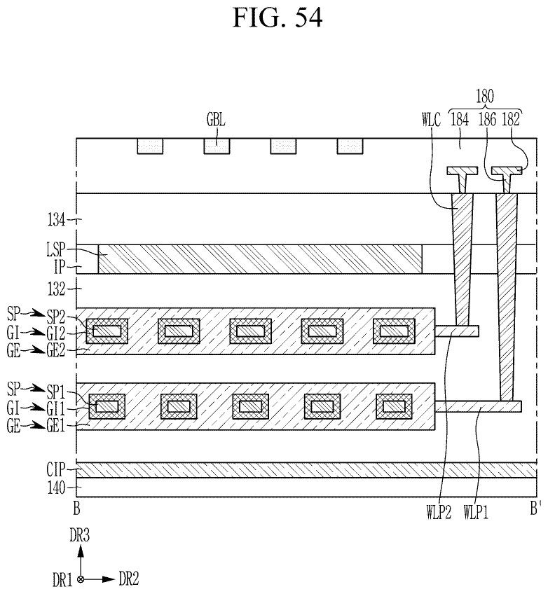

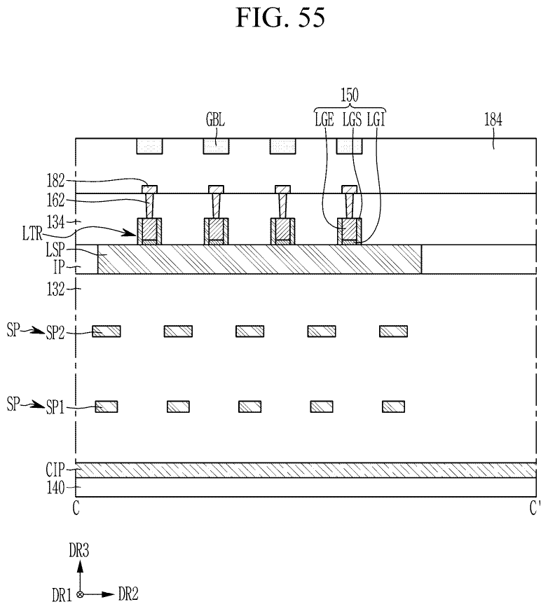

The semiconductor device according to the embodiments may have the structure illustrated in FIGS. 1 to 5 or the structure illustrated in FIGS. 7 to 9 depending on the manufacturing method. Hereinafter, the method of manufacturing the semiconductor device illustrated in FIGS. 1 to 5 will be described with reference to FIGS. 10 to 33, and the method of manufacturing the semiconductor device illustrated in FIGS. 7 to 9 will be described with reference to FIGS. 34 to 55.

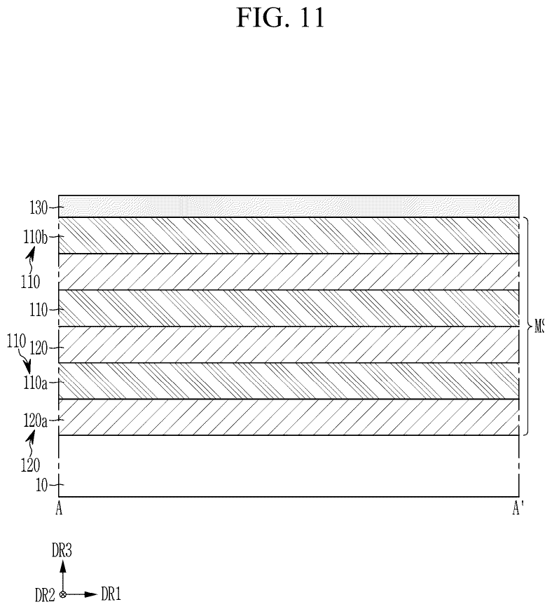

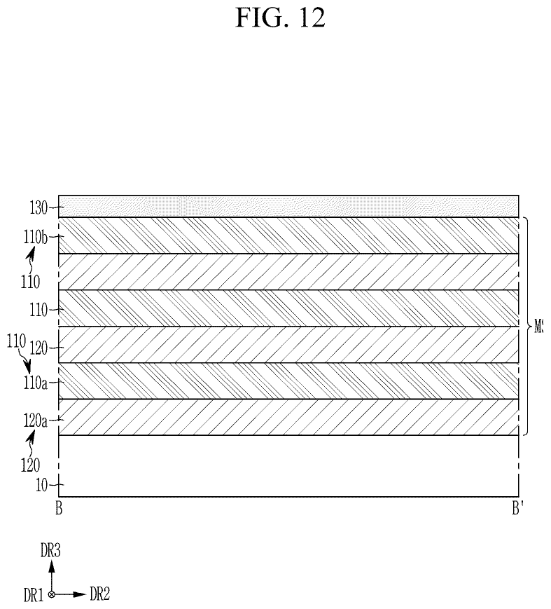

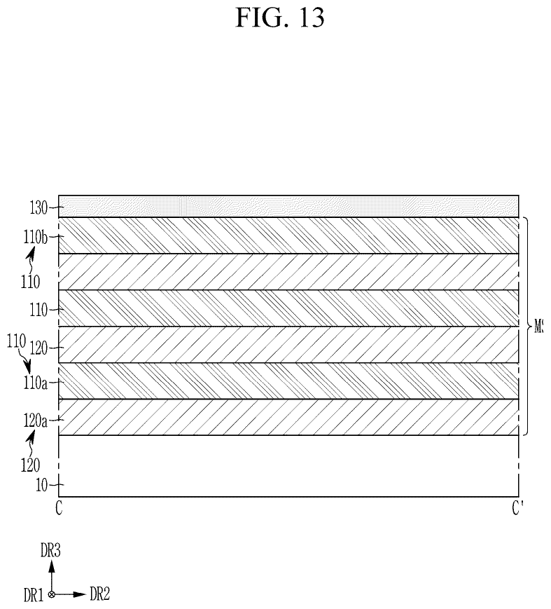

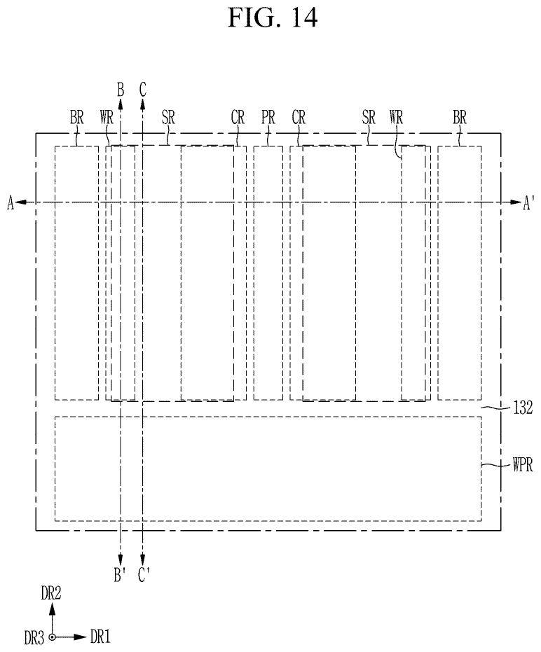

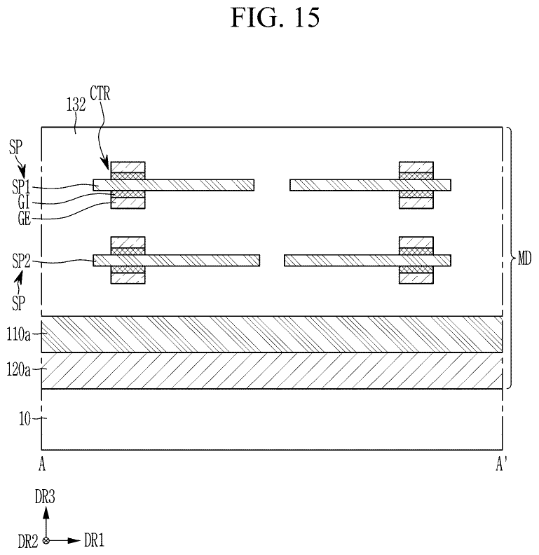

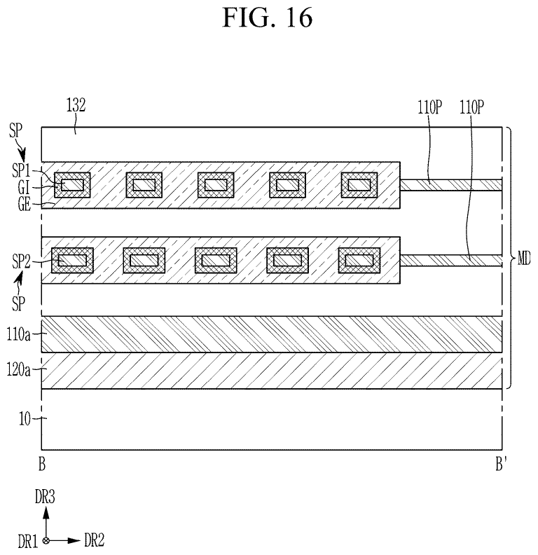

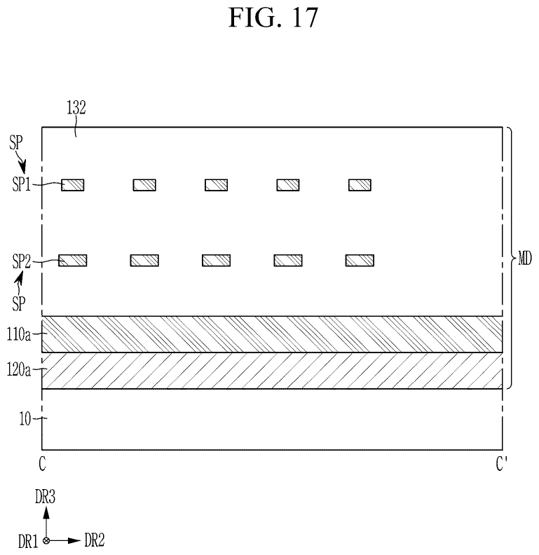

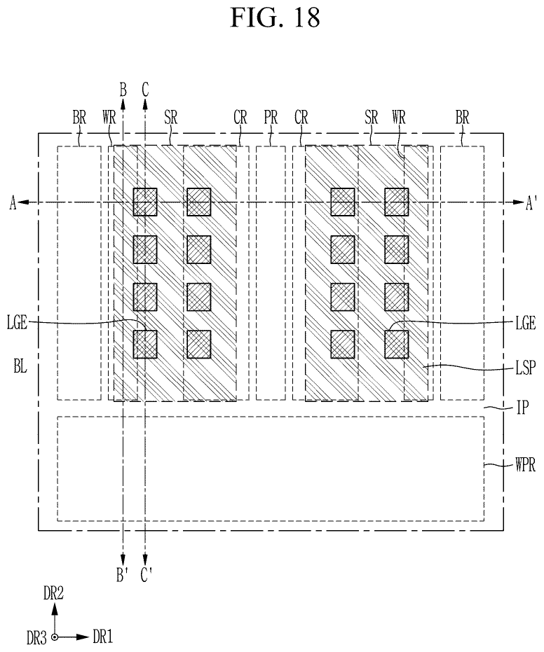

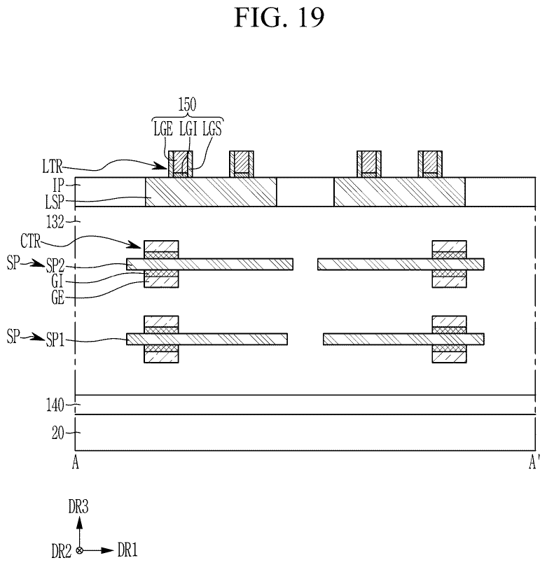

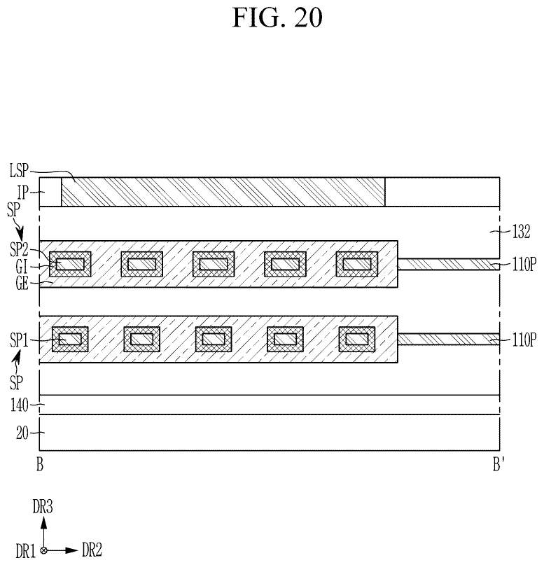

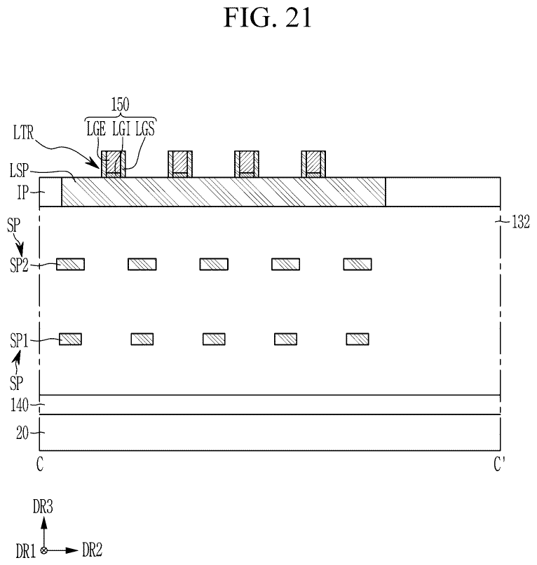

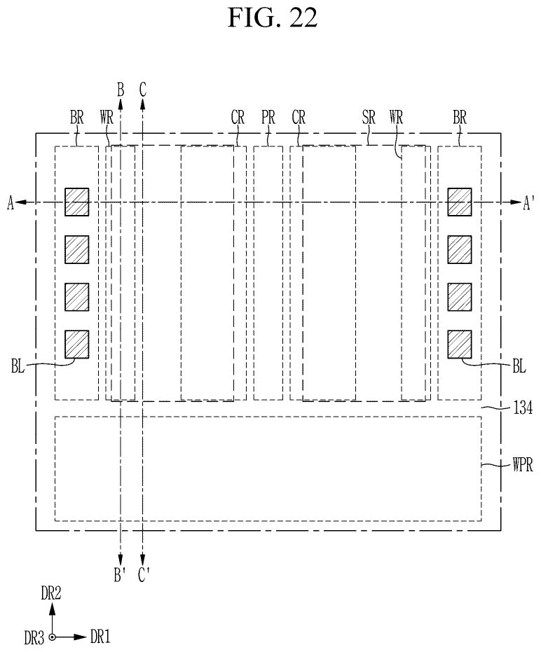

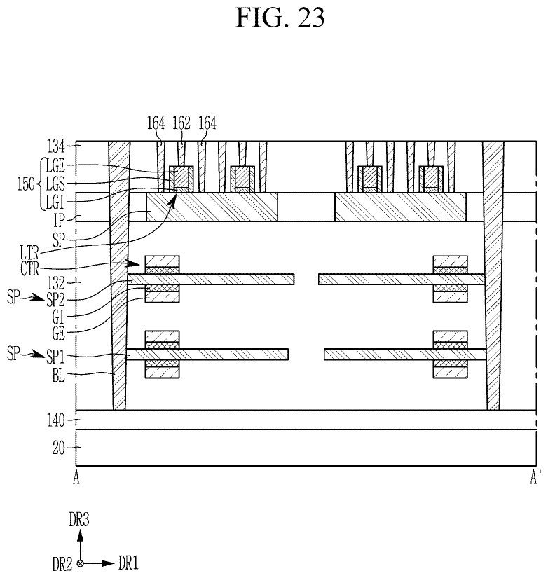

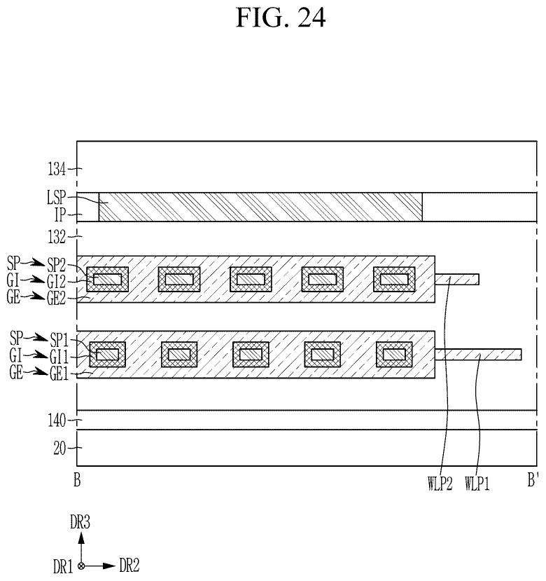

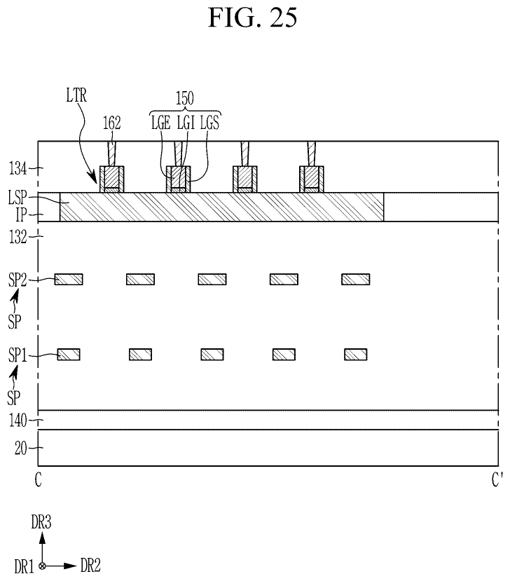

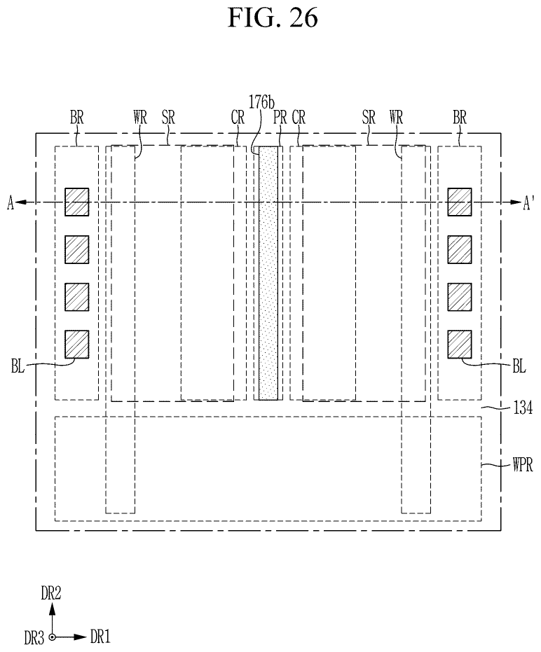

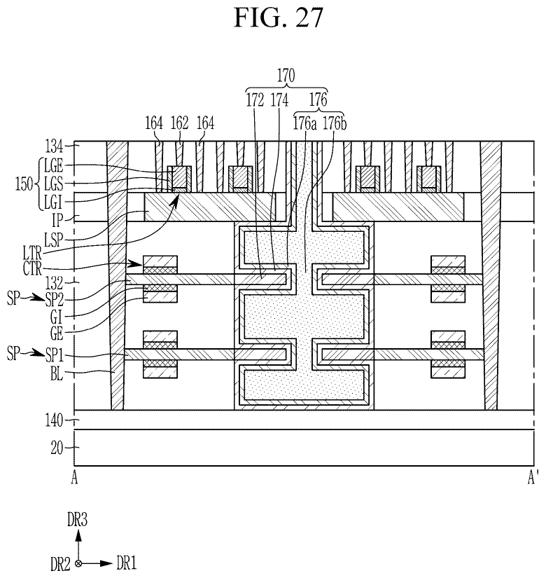

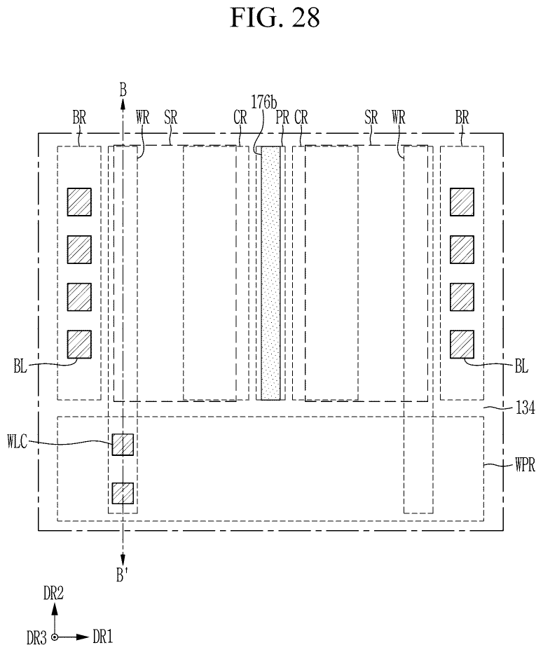

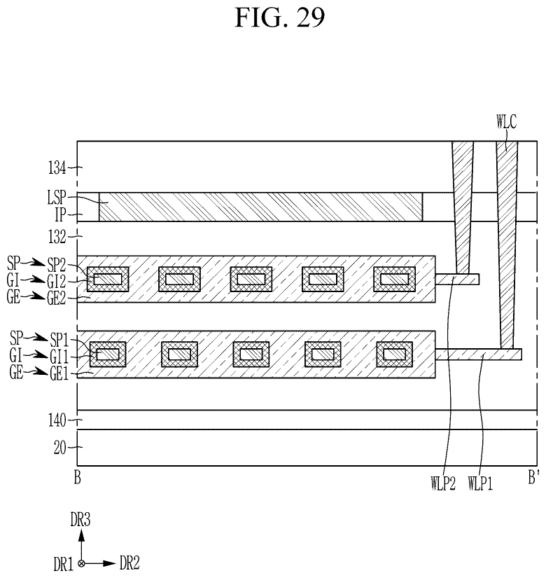

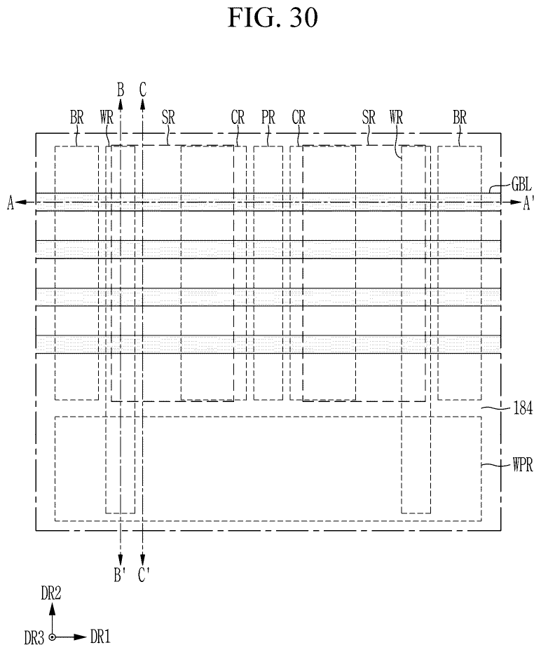

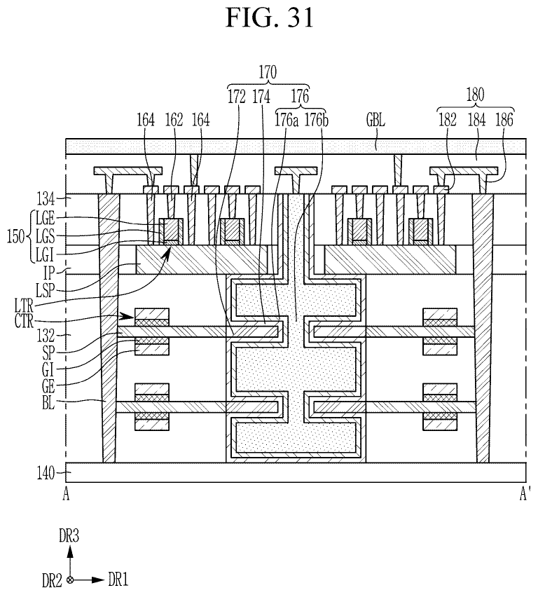

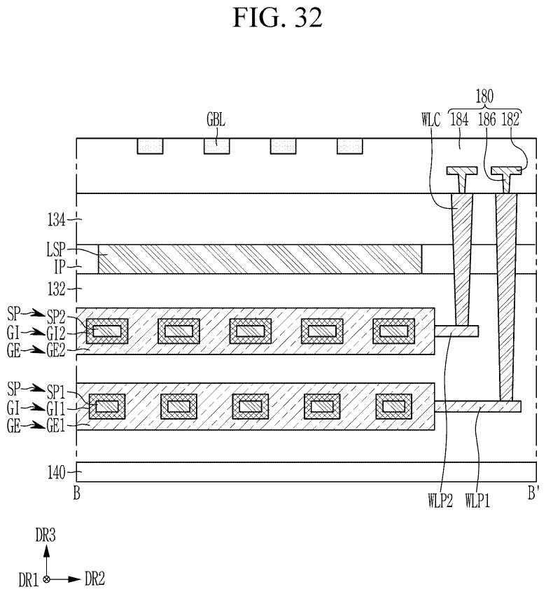

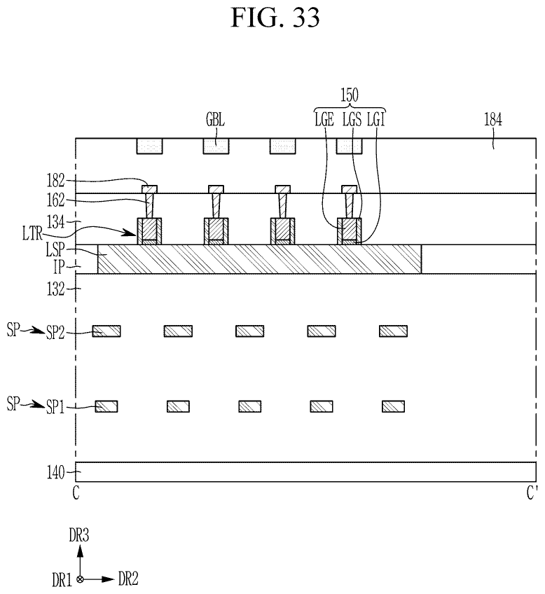

FIGS. 10 to 33 are drawings showing a method of manufacturing a semiconductor device according to an embodiment. FIGS. 10, 14, 18, 22, 26, 28, and 30 are top plan views. FIG. 11, FIG. 15, FIG. 19, FIG. 23, FIG. 27, and FIG. 31 are cross-sectional views taken along line A-A′ of the top plan views of FIG. 10, FIG. 14, FIG. 18, FIG. 22, FIG. 26, and FIG. 30, respectively. FIG. 12, FIG. 16, FIG. 20, FIG. 24, FIG. 29, and FIG. 32 are cross-sectional views taken along line B-B′ of the top plan views of FIG. 10, FIG. 14, FIG. 18, FIG. 22, FIG. 28, and FIG. 30, respectively. FIG. 13, FIG. 17, FIG. 21, FIG. 25, and FIG. 33 are cross-sectional views taken along line C-C′ of the top plan views of FIG. 10, FIG. 14, FIG. 18, FIG. 22, and FIG. 30, respectively.

The bit line region BR, the word line region WR, the semiconductor region SR, the capacitor region CR, the plate region PR, and the word line pad region WPR shown in FIGS. 10, 14, 18, 22, 26, 28, and 30 may be planar representations of regions where bit lines BL, cell gate electrodes GE, logic semiconductor patterns LSP, capacitors 170, second electrodes 176, and cell gate connection pads WLP are disposed to be formed in the processes described below.

Referring to FIGS. 10 to 13, a first layer 110 and a second layer 120 are alternately and repeatedly stacked on a substrate 10 to form a mold structure MS, and a mold upper insulating layer 130 may be formed on the mold structure MS. The substrate 10 may include a semiconductor material. The first layer 110 may include a first material, and the second layer 120 may include a second material different from the first material. Each of the first material and the second material may be a semiconductor material, and the first material and the second material may have an etching selectivity. For example, the first material may be silicon and the second material may be carbon-doped silicon germanium, but is not limited thereto.

The mold structure MS may include a plurality of first layers 110 and a plurality of second layers 120. The mold structure MS may be disposed on the first surface of the substrate 10. For example, the second layer 120 may be first disposed on the first surface of the substrate 10, and the first layer 110 may be disposed on the second layer 120. That is, the plurality of first layers 110 and the plurality of second layers 120 may be alternately and repeatedly disposed in the order of the second layer 120, the first layer 110, the second layer 120, and the first layer 110 on the first surface of the substrate 10.

Hereinafter, the second layer 120 disposed directly on the first surface of the substrate 10 may be referred to as a contact layer 120a. Among the plurality of first layers 110, the first layer 110 that is closest to the first surface of the substrate 10 may be referred to as an adjacent layer 110a. Among the plurality of first layers 110, the first layer 110 that is furthest from the first surface of the substrate 10 may be referred to as a remote layer 110b.

The mold upper insulating layer 130 may cover the upper surface of the top layer of the mold structure MS. For example, the top layer of the mold structure MS may be the first layer 110. The first layer 110, which is the top layer of the mold structure MS, may be the remote layer 110b.

The mold upper insulating layer 130 may include an insulating material such as silicon oxide, silicon nitride, or silicon oxynitride.

Referring to FIGS. 14 to 17, the remaining layers except for the contact layer 120a among the plurality of second layers 120 may be removed, and the remaining layers except for the adjacent layer 110a among the plurality of first layers 110 may be patterned to form the plurality of cell semiconductor patterns SP. Therefore, adjacent layer 110a remains unpatterned at this stage, although it will be patterned in subsequent steps.

For example, the remaining layers except for the contact layer 120a among the plurality of second layers 120 may be removed through a selective etching process. Accordingly, the upper surface of the adjacent layer 110a among the plurality of first layers 110 may be exposed, and the upper and lower surfaces of the remaining layers except for the adjacent layer 110a among the plurality of first layers 110 may be exposed.

Next, the thickness of the remaining layers except for the adjacent layer 110a among the plurality of first layers 110 may be reduced through a thinning process, but the thinning process may not necessarily be involved.

Next, the remaining layers except for the contact layer 120a among the plurality of second layers 120 may be removed and the remaining space may be filled with an insulating material to form the interlayer insulating layer 132.

Next, the mold upper insulating layer 130 may be patterned to form a first insulating pattern, and the first insulating pattern may be used as an etching mask for patterning the remaining layers of the plurality of first layers 110 except for the adjacent layer 110a. By performing an etching process using the first insulating pattern as an etching mask, a first trench may be formed that separates the remaining layers, except for the adjacent layer 110a, among the plurality of first layers 110 in the first direction DR1. In this case, the etching process may use the adjacent layer 110a as an etch-stop layer. The first trench may penetrate the remaining layers of the plurality of first layers 110 except for the adjacent layer 110a in the third direction DR3. According to an embodiment, the width of the first trench in the first direction DR1 may become narrower as a distance from the upper surface of the adjacent layer 110a decreases.

Next, the first insulating pattern may be removed, and an insulating layer covering the interlayer insulating layer 132 may be formed. The insulating layer may be patterned to form a second insulating pattern, and the second insulating pattern may be used as an etching mask for patterning the remaining layers of the plurality of first layers 110 except for the adjacent layer 110a. By performing an etching process using the second insulating pattern as an etching mask, a second trench may be formed that separates the remaining layers, except for the adjacent layer 110a, among the plurality of first layers 110 in the second direction DR2. In this case, the etching process may use the adjacent layer 110a as an etch-stop layer. The second trench may penetrate the remaining layers of the plurality of first layers 110 except for the adjacent layer 110a in the third direction DR3. According to an embodiment, the width of the second trench in the first direction DR1 may become narrower as a distance from the upper surface of the adjacent layer 110a decreases. After the etching process is completed, the second insulating pattern may be removed.

Accordingly, the plurality of cell semiconductor patterns SP may be formed that are spaced apart from each other in the first direction DR1 and the second direction DR2 and stacked in the third direction DR3. Among the plurality of first layers 110, at least a portion of a remaining portion 110P in which the plurality of cell semiconductor patterns SP are formed, except for the adjacent layer 110a, may be replaced with the cell gate connection pad WLP in a subsequent process. The remaining portion 110P may be disposed on an extension line in the second direction DR2 of the plurality of cell semiconductor patterns SP. The remaining portion 110P may be disposed in the word line pad region WPR of FIG. 14.

The plurality of cell semiconductor patterns SP may include the first cell semiconductor pattern SP1 and the second cell semiconductor pattern SP2 that are stacked in the third direction DR3. For example, the second cell semiconductor pattern SP2 may be closer to the upper surface of the adjacent layer 110a than the first cell semiconductor pattern SP1. According to an embodiment, the width of the first cell semiconductor pattern SP1 in the first direction DR1 may be shorter than the width of the second cell semiconductor pattern SP2 in the first direction DR1. The width of the first cell semiconductor pattern SP1 in the second direction DR2 may be shorter than the width of the second cell semiconductor pattern SP2 in the second direction DR2.

Next, a portion of the interlayer insulating layer 132 surrounding the plurality of cell semiconductor patterns SP may be removed through a selective etching process, and the cell gate insulating layer GI surrounding a portion of each of the plurality of cell semiconductor patterns SP may be formed through a deposition process. The deposition process for forming the cell gate insulating layer GI may use, for example, an atomic layer deposition (ALD) process or a chemical vapor deposition (CVD) process. Next, the cell gate electrode GE covering the cell gate insulating layer GI may be formed. For example, the CVD process may be performed to remove a portion of the interlayer insulating layer 132 through the selective etching process, thereby forming the cell gate electrode GE that fills the remaining space. Accordingly, the cell transistor CTR including the cell gate electrode GE and the cell semiconductor pattern SP may be formed.

The cell gate electrode GE may have a line shape extending in the second direction DR2. The cell gate electrode GE may surround the plurality of cell semiconductor patterns SP disposed in the second direction DR2. The cell gate electrode GE may be separated from the cell gate electrode GE by the cell gate insulating layer GI. The cell gate electrode GE may be disposed in the word line region WR of FIG. 14.

The structure formed on the substrate 10 according to the above-described processes may be referred to as an intermediate structure MD hereinafter.

Referring to FIGS. 18 to 21, the intermediate structure MD on the substrate 10 may be flipped and attached on the lower insulating layer 140 disposed on a carrier substrate 20. Accordingly, the interlayer insulating layer 132 may be disposed on the upper surface of the lower insulating layer 140.

The plurality of cell semiconductor patterns SP may include the first cell semiconductor pattern SP1 and the second cell semiconductor pattern SP2 that are stacked in the third direction DR3. By flipping the intermediate structure MD, the first cell semiconductor pattern SP1 may be closer to the upper surface of the lower insulating layer 140 than the second cell semiconductor pattern SP2. According to an embodiment, the width of the first cell semiconductor pattern SP1 in the first direction DR1 may be shorter than the width of the second cell semiconductor pattern SP2 in the first direction DR1. The width of the first cell semiconductor pattern SP1 in the second direction DR2 may be shorter than the width of the second cell semiconductor pattern SP2 in the second direction DR2.

Next, the substrate 10 and the contact layer 120a may be removed.

Next, the adjacent layer 110a may be patterned to form at least one logic semiconductor pattern LSP. For example, a photoresist pattern may be formed on the adjacent layer 110a through an exposing and developing process, and an etching process may be performed using a photoresist pattern as an etching mask to form a third trench penetrating the adjacent layer 110a in the third direction DR3. The insulating pattern IP may be formed by filling an insulating material in the third trench. The insulating pattern IP may serve as device isolation. The logic semiconductor pattern LSP may be defined by the insulating pattern IP. The logic semiconductor pattern LSP may be disposed in the semiconductor region SR of FIG. 18.

Next, at least one logic gate structure 150 may be formed on the logic semiconductor pattern LSP. For example, the logic gate insulating layer LGI may be formed on the logic semiconductor pattern LSP, and the logic gate electrode LGE may be formed on the logic gate insulating layer LGI. Next, the logic gate spacer LGS covering both side surfaces of the logic gate electrode LGE and both side surfaces of the logic gate insulating layer LGI may be formed. Next, the first source/drain region and the second source/drain region may be formed by doping impurities into the logic semiconductor pattern LSP disposed on both sides of the logic gate electrode LGE. Accordingly, the logic transistor LTR including the logic gate electrode LGE and the logic semiconductor pattern LSP may be formed.

Referring to FIGS. 22 to 25, the upper insulating layer 134 covering the logic gate electrode LGE, the logic semiconductor pattern LSP, and the insulating pattern IP may be formed. The upper insulating layer 134 may cover the upper surface of the logic gate electrode LGE, the upper surface of the insulating pattern IP, and the upper surface of the logic semiconductor pattern LSP. The upper insulating layer 134 may cover the upper surface and side surfaces of the logic gate spacer LGS.

Next, the logic gate contact 162 and the pair of source/drain contacts 164 penetrating the upper insulating layer 134 may be formed. For example, after forming contact holes penetrating the upper insulating layer 134, the internal space of the contact holes may be filled with a metal material to form the logic gate contact 162 and the source/drain contact 164. The logic gate contact 162 may penetrate the upper insulating layer 134 and contact the upper surface of the logic gate electrode LGE. The pair of source/drain contacts 164 may penetrate the upper insulating layer 134 and contact the upper surface of the logic semiconductor pattern LSP disposed on both sides of the logic gate electrode LGE. One of the pair of source/drain contacts 164 may be connected to the first source/drain region, and the other of the pair of source/drain contacts 164 may be connected to the second source/drain region.

Next, a fourth trench penetrating the upper insulating layer 134, the insulating pattern IP, and the interlayer insulating layer 132 may be formed. The fourth trench may be formed through a process of etching the upper insulating layer 134, the insulating pattern IP, and the interlayer insulating layer 132 in the third direction DR3, and the etching process for forming the fourth trench may use the lower insulating layer 140 as an etch-stop layer. As the fourth trench is formed, one end of each of the plurality of cell semiconductor patterns SP may be exposed. For example, one end of each of the plurality of cell semiconductor patterns SP in the first direction DR1 may be exposed. The surface of each exposed end of the plurality of cell semiconductor patterns SP may be doped with impurities.

Next, a conductive material may be filled into the fourth trench to form the bit line BL. The bit line BL may contact one end of each of the plurality of cell semiconductor patterns SP. The bit line BL may have a pillar shape extending in the third direction DR3. The plurality of cell semiconductor patterns SP stacked in the third direction DR3 may be connected to a single bit line BL. The diameter of the bit line BL (for example, a width in the first direction DR1) may decrease as a distance from the upper surface of the lower insulating layer 140 decreases, which may correspond to the sidewall profile of the fourth trench.

The bit line BL may be formed in the bit line BL region of FIG. 22. In FIG. 22, the planar shape of the bit line BL is illustrated as being quadrangle, but is not limited thereto and may be variously changed to a circular shape, an elliptical shape, or another polygonal shape.

Next, the remaining portions 110P of the first layer 110 disposed on the same layer as each of the plurality of cell semiconductor patterns SP may be replaced with a conductive material to form the plurality of cell gate connection pads WLP connected to each of the plurality of cell gate electrodes GE. Each of the plurality of cell gate connection pads WLP may be connected to each of the plurality of cell gate electrodes GE in the second direction DR2. The plurality of cell gate connection pads WLP may be disposed in the word line pad region WPR of FIG. 22.

For example, the plurality of cell gate electrodes GE may include the first cell gate electrode GE1 surrounding the first cell semiconductor pattern SP1 and the second cell gate electrode GE2 surrounding the second cell semiconductor pattern SP2. The first cell gate insulating layer GI1 may be disposed between the first cell gate electrode GE1 and the first cell semiconductor pattern SP1, and the second cell gate insulating layer GI2 may be disposed between the second cell gate electrode GE2 and the second cell semiconductor pattern SP2. The plurality of cell gate connection pads WLP may include the first cell gate connection pad WLP1 connected to the first cell gate electrode GE1 and the second cell gate connection pad WLP2 connected to the second cell gate electrode GE2.

For example, the first cell semiconductor pattern SP1 may be closer to the upper surface of the lower insulating layer 140 than the second cell semiconductor pattern SP2. The first cell gate electrode GE1 surrounding the first cell semiconductor pattern SP1 may be closer to the upper surface of the lower insulating layer 140 than the second cell gate electrode GE2 surrounding the second cell semiconductor pattern SP2. The first cell gate connection pad WLP1 connected to the first cell gate electrode GE1 may be closer to the upper surface of the lower insulating layer 140 than the second cell gate connection pad WLP2 connected to the second cell gate electrode GE2.

The plurality of cell gate connection pads WLP may be longer in the second direction DR2 in which each of the plurality of cell gate electrodes GE extends as a distance from the upper surface of the lower insulating layer 140 decreases. For example, the first cell gate connection pad WLP1 may be longer in the second direction DR2 than the second cell gate connection pad WLP2. The plurality of cell gate connection pads WLP may have a stepped structure.

Referring to FIG. 26 and FIG. 27, a fifth trench penetrating the upper insulating layer 134, the insulating pattern IP, and the interlayer insulating layer 132 may be formed, and the plurality of capacitors 170 may be formed through the fifth trench. The fifth trench may be formed through a process of etching the upper insulating layer 134, the insulating pattern IP, and the interlayer insulating layer 132 in the third direction DR3, and the etching process for forming the fifth trench may use the lower insulating layer 140 as an etch-stop layer. The bottom surface of the fifth trench may be defined by the upper surface of the lower insulating layer 140. The sidewall of the fifth trench may be defined by the sidewall of the upper insulating layer 134, the sidewall of the insulating pattern IP, the sidewall of the interlayer insulating layer 132, and the sidewall of each of the plurality of cell semiconductor patterns SP. As the fifth trench is formed, the plurality of cell semiconductor patterns SP may be exposed.

Next, a portion of each of the plurality of cell semiconductor patterns exposed through the fifth trench may be etched to form a plurality of first recesses. The first recess may be formed by etching the cell semiconductor pattern SP in the first direction DR1. As the first recess is formed, the other end of the cell semiconductor pattern SP may be exposed. For example, the other end of each of the plurality of cell semiconductor patterns SP in the first direction DR1 may be exposed. The first recess may be used to dope impurities onto the surface of the exposed other end of each of the plurality of cell semiconductor patterns SP.

Next, a conductive material may be filled in the plurality of first recesses to form the plurality of first electrodes 172. Each of the plurality of first electrodes 172 may be in contact with the other end of each of the plurality of cell semiconductor patterns SP. Each of the plurality of first electrodes 172 may be connected to each of the plurality of cell semiconductor patterns SP in the first direction DR1.

Next, a portion of the interlayer insulating layer 132 exposed through the fifth trench may be etched to form a plurality of second recesses. A portion of the plurality of second recesses may have side walls defined by surfaces of the plurality of first electrodes 172 facing in the third direction DR3, and bottom surfaces defined by side surfaces of the interlayer insulating layer 132. Another portion of the plurality of second recesses may have sidewalls defined by the upper surface of the first electrode 172, the lower surfaces of the logic semiconductor pattern LSP and the insulating pattern IP, and a bottom surface defined by the side surfaces of the interlayer insulating layer 132. The other portion of the plurality of second recesses may have side walls defined by the lower surface of the first electrode 172 and the upper surface of the lower insulating layer 140, and a bottom surface defined by the side surface of the interlayer insulating layer 132. Each of the plurality of second recesses may be formed by etching the interlayer insulating layer 132 disposed between the plurality of cell semiconductor patterns SP, between a top cell semiconductor pattern SP and the logic semiconductor pattern LSP, and between a bottom cell semiconductor pattern SP and the lower insulating layer 140 in the first direction DR1.

Next, the dielectric layer 174 and the first conductive layer 176a covering the sidewalls and bottom surfaces of the plurality of second recesses and the sidewalls and bottom surface of the fifth trench may be formed. The dielectric layer 174 may be formed first, and then the first conductive layer 176a may be formed on the dielectric layer 174. Accordingly, the dielectric layer 174 may be disposed between the plurality of first electrodes 172 and the first conductive layer 176a.

Each of the dielectric layer 174 and the first conductive layer 176a may have a conformal shape. Each of the dielectric layer 174 and the first conductive layer 176a may have the same shape as the surface profile of the fifth trench and the plurality of second recesses.

Next, the remaining space of the plurality of second recesses and the remaining space of the fifth trench may be filled with a conductive material to form the second conductive layer 176b. For example, the first conductive layer 176a and the second conductive layer 176b may include different conductive materials. The first conductive layer 176a may include the same conductive material as the first electrode 172, and the second conductive layer 176b may include a different conductive material than the first electrode 172. For example, the first conductive layer 176a may include a metal (for example, titanium nitride), and the second conductive layer 176b may include a doped semiconductor material (for example, doped silicon germanium).

The first conductive layer 176a and the second conductive layer 176b may form the second electrode 176. According to an embodiment, each of the plurality of first electrodes 172 is spaced apart from each other, and each of the dielectric layer 174, the first conductive layer 176a, and the second conductive layer 176b may be formed integrally. The second electrode 176 may be spaced apart from the plurality of first electrodes 172 by the dielectric layer 174. The plurality of first electrodes 172, the dielectric layer 174, and the second electrode 176 may form the plurality of capacitors 170. Each of the plurality of capacitors 170 may be defined by the first electrode 172, the second electrode 176 surrounding the first electrode 172, and the dielectric layer 174 interposed between the first electrode 172 and the second electrode 176. The second electrode 176 may be disposed in the plate region PR of FIG. 26, and the plurality of capacitors 170 may be disposed in the capacitor region CR of FIG. 26.

Referring to FIGS. 28 and 29, a plurality of sixth trenches penetrating the upper insulating layer 134, the insulating pattern IP, and the interlayer insulating layer 132 may be formed. The plurality of sixth trenches may be formed through a process of etching the upper insulating layer 134, the insulating pattern IP, and the interlayer insulating layer 132 in the third direction DR3, and the etching process for forming the plurality of sixth trenches may use the cell gate connection pad WLP as an etch-stop layer.

Next, the plurality of sixth trenches may be filled with a conductive material to form the plurality of cell gate contacts WLC. Each of the plurality of cell gate contacts WLC may contact the upper surface of each of the plurality of cell gate connection pads WLP. Each of the plurality of cell gate connection pads WLP may be connected to each of the plurality of cell gate electrodes GE stacked in the third direction DR3. The cell gate contact WLC may have a pillar shape extending in the third direction DR3. The diameter of the cell gate contact WLC (for example, a width in the second direction DR2) may decrease as a distance from the upper surface of the cell gate connection pad WLP decreases, which may correspond to the sidewall profile of the sixth trench.

The cell gate contact WLC may be disposed in the word line pad region WPR of FIG. 28. In FIG. 28, the planar shape of the cell gate contact WLC is illustrated as being quadrangle, but is not limited thereto and may be variously changed to a circular shape, an elliptical shape, or another polygonal shape.

Referring to FIGS. 30 to 33, the wiring layer 180 and the global bit line GBL may be formed on the upper insulating layer 134. For example, the wiring insulating layer 184 may be formed on the upper insulating layer 134, and then a conductive material may be deposited after patterning the wiring insulating layer 184 to form the plurality of wirings 182, the plurality of vias 186, and the global bit line GBL. The plurality of wirings 182 may be formed of a plurality of layers, and the plurality of vias 186 may connect the plurality of wirings 182 disposed in different layers. The plurality of wirings 182 and the plurality of vias 186 may be connected to the global bit line GBL, the bit line BL, the cell gate contact WLC, the second electrode 176 of the plurality of capacitors 170, the logic gate contact 162, and the source/drain contact 164.

The two side surfaces and the bottom surface of the global bit line GBL may be surrounded by a wiring insulating layer 184, but is not necessarily limited thereto. For example, a wiring insulating layer 184 may be further disposed on the upper surface of the global bit line GBL. The plurality of wirings 182 surrounded by the wiring insulating layer 184 on the upper surface of the global bit line GBL and the plurality of vias 186 penetrating the wiring insulating layer 184 may be further disposed.

According to an embodiment, the wiring layer 180 may connect the global bit line GBL and the logic transistor LTR, and may connect the bit line BL and the logic transistor LTR. For example, the wiring layer 180 may connect the global bit line GBL to one of the pair of source/drain contacts 164 that are connected to a pair of source/drain regions of the logic transistor LTR, and may connect the bit line BL to the other of the pair of source/drain contacts 164. That is, the logic transistor LTR may be connected between the global bit line GBL and the bit line BL.

After completing the above-described processes, the carrier substrate 20 may be removed.

As described above with reference to FIGS. 10 to 33, the logic transistor LTR may be formed first, and then the plurality of capacitors 170 may be formed later. Accordingly, the logic transistor LTR may be formed in the upper region of the plurality of capacitors 170 while ensuring the reliability of the plurality of capacitors 170. The upper region of the plurality of capacitors 170 may refer to as a region that overlaps the plurality of capacitors 170 in the third direction DR3 and is further apart from the upper surface of the lower insulating layer 140 than the plurality of capacitors 170.

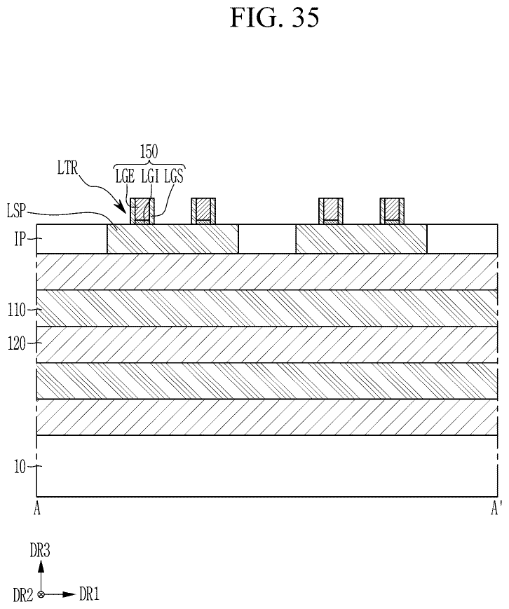

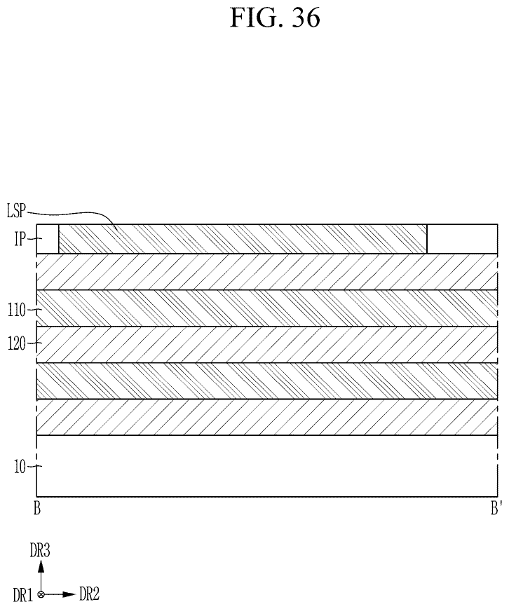

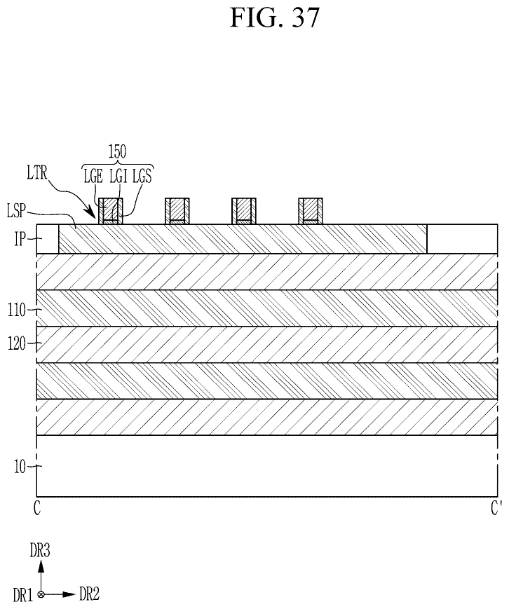

FIGS. 34 to 55 are drawings showing a method of manufacturing a semiconductor device according to an embodiment. FIGS. 34, 38, 42, 46, 48, and 52 are top plan views. FIGS. 35, 39, 43, 47, 49, and 53 are cross-sectional views taken along line A-A′ of the top plan views of FIGS. 34, 38, 42, 46, 48, and FIG. 52, respectively. FIGS. 36, 40, 44, 50, and FIG. 54 are cross-sectional views taken along line B-B′ of the top plan views of FIGS. 34, 38, 42, 48, and 52, respectively. FIGS. 37, 41, 45, 51, and 55 are cross-sectional views taken along line C-C′ of the top plan views of FIGS. 34, 38, 42, 48, and FIG. 52, respectively.

The processes of FIGS. 34 to 55 described below may be performed after the processes of FIGS. 10 to 13 are performed. That is, a method of manufacturing a semiconductor device according to an embodiment may include the processes of FIGS. 10 to 13 prior to the processes of FIGS. 34 to 55. Hereinafter, the descriptions of the processes of FIGS. 10 to 13 are brief or omitted.

According to an embodiment, the substrate 10 and the mold structure MS on the substrate 10 of FIGS. 10 to 13 may be provided. The mold upper insulating layer 130 may be disposed on the mold structure MS. The remote layer 110b among the plurality of first layers 110 may be patterned using the mold upper insulating layer 130.

For example, the first insulating pattern may be formed by patterning the mold upper insulating layer 130, and an etching process may be performed using the first insulating pattern as an etching mask on the remote layer 110b to form the first trench penetrating the remote layer 110b in the third direction DR3. The first trench may be filled with an insulating material to form the insulating pattern IP. The insulating pattern IP may serve as device isolation. The logic semiconductor pattern LSP may be defined by the insulating pattern IP. The logic semiconductor pattern LSP may be disposed in the semiconductor region SR of FIG. 34.

Next, at least one logic gate structure 150 may be formed on the logic semiconductor pattern LSP. For example, the logic gate insulating layer LGI may be formed on the logic semiconductor pattern LSP, and the logic gate electrode LGE may be formed on the logic gate insulating layer LGI. Next, the logic gate spacer LGS covering both side surfaces of the logic gate electrode LGE and both side surfaces of the logic gate insulating layer LGI may be formed. Next, the first source/drain region and the second source/drain region may be formed by doping impurities into the logic semiconductor pattern LSP disposed on both sides of the logic gate electrode LGE. Accordingly, the logic transistor LTR including the logic gate electrode LGE and the logic semiconductor pattern LSP may be formed.

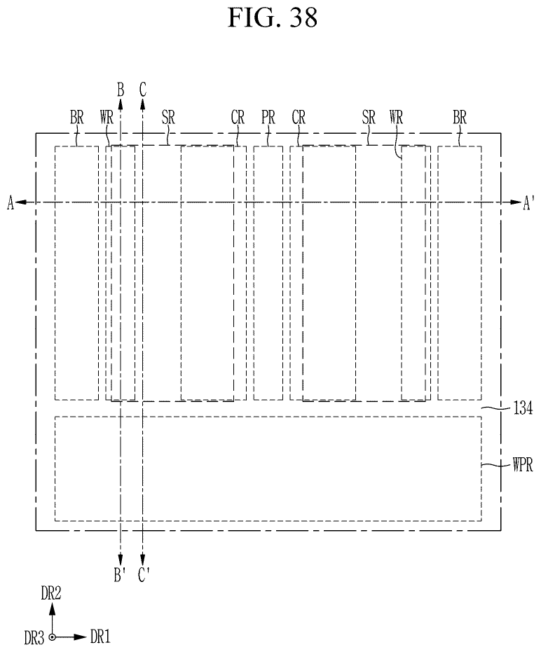

Referring to FIGS. 38 to 41, the upper insulating layer 134 covering the logic gate electrode LGE, the logic semiconductor pattern LSP, and the insulating pattern IP may be formed. The upper insulating layer 134 may cover the upper surface of the logic gate electrode LGE, the upper surface of the insulating pattern IP, and the upper surface of the logic semiconductor pattern LSP. The upper insulating layer 134 may cover the upper surface and side surfaces of the logic gate spacer LGS.

Next, the logic gate contact 162 and the pair of source/drain contacts 164 penetrating the upper insulating layer 134 may be formed. For example, after forming contact holes penetrating the upper insulating layer 134, the internal space of the contact holes may be filled with a metal material to form the logic gate contact 162 and the source/drain contact 164. The logic gate contact 162 may penetrate the upper insulating layer 134 and contact the upper surface of the logic gate electrode LGE. The pair of source/drain contacts 164 may penetrate the upper insulating layer 134 and contact the upper surface of the logic semiconductor pattern LSP disposed on both sides of the logic gate electrode LGE. One of the pair of source/drain contacts 164 may be connected to the first source/drain region, and the other of the pair of source/drain contacts 164 may be connected to the second source/drain region.

The structure formed on the substrate 10 according to the above-described processes may be referred to as a first intermediate structure MD1 hereinafter.

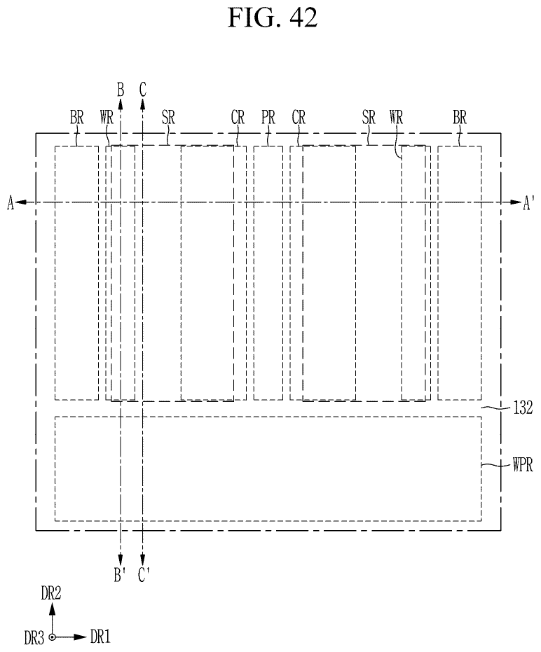

Referring to FIGS. 42 to 45, the intermediate structure MD1 on the substrate 10 may be flipped and attached on an etch-stop layer 22 disposed on a first carrier substrate 20. Accordingly, the upper insulating layer 134 may be disposed on the upper surface of the etch-stop layer 22. Next, the substrate 10 may be removed and an insulating layer covering the contact layer 120a may be formed.

Next, the plurality of second layers 120 may be removed and the remaining space may be filled with an insulating material to form the interlayer insulating layer 132.

Next, the insulating layer may be patterned to form the second insulating pattern, and the second insulating pattern may be used as an etching mask for patterning the remaining layers of the plurality of first layers 110 except for the logic semiconductor pattern LSP. By performing an etching process using the second insulating pattern as an etching mask, the second trench may be formed that separates the remaining layers, except for the logic semiconductor pattern LSP, among the plurality of first layers 110 in the first direction DR1. In this case, the etching process may proceed up to the upper surface of the etch-stop layer 22. The second trench may penetrate through the remaining layers of the plurality of first layers 110 except for the logic semiconductor pattern LSP in the third direction DR3. According to an embodiment, the width of the second trench in the first direction DR1 may become narrower as a distance from the upper surface of the etch-stop layer 22 decreases.

Next, the second insulating pattern may be removed, and an insulating layer covering the interlayer insulating layer 132 may be formed. The insulating layer may be patterned to form a third insulating pattern, and the third insulating pattern may be used as an etching mask for patterning the remaining layers of the plurality of first layers 110 except for the logic semiconductor pattern LSP. By performing an etching process using the third insulating pattern as an etching mask, the third trench may be formed that separates the remaining layers, except for the logic semiconductor pattern LSP, among the plurality of first layers 110 in the second direction DR2. In this case, the etching process may proceed up to the upper surface of the etch-stop layer 22. The third trench may penetrate through the remaining layers of the plurality of first layers 110 except for the logic semiconductor pattern LSP in the third direction DR3. According to an embodiment, the width of the third trench in the first direction DR1 may become narrower as a distance from the upper surface of the etch-stop layer 22 decreases. After the etching process is completed, the third insulating pattern may be removed.

Accordingly, the plurality of cell semiconductor patterns SP may be formed that are spaced apart from each other in the first direction DR1 and the second direction DR2 and stacked in the third direction DR3. Among the plurality of first layers 110, at least a portion of the remaining portion 110P in which the plurality of cell semiconductor patterns SP are formed, except for the logic semiconductor pattern LSP, may be replaced with the cell gate connection pad WLP in a subsequent process. The remaining portion 110P may be disposed on an extension line in the second direction DR2 of the plurality of cell semiconductor patterns SP. The remaining portion 110P may be disposed in the word line pad region WPR of FIG. 42.

The plurality of cell semiconductor patterns SP may include the first cell semiconductor pattern SP1 and the second cell semiconductor pattern SP2 that are stacked in the third direction DR3. For example, the second cell semiconductor pattern SP2 may be closer to the upper surface of the etch-stop layer 22 than the first cell semiconductor pattern SP1. According to an embodiment, the width of the first cell semiconductor pattern SP1 in the first direction DR1 may be shorter than the width of the second cell semiconductor pattern SP2 in the first direction DR1. The width of the first cell semiconductor pattern SP1 in the second direction DR2 may be shorter than the width of the second cell semiconductor pattern SP2 in the second direction DR2.

Next, a portion of the interlayer insulating layer 132 surrounding the plurality of cell semiconductor patterns SP may be removed through a selective etching process, and the cell gate insulating layer GI surrounding a portion of each of the plurality of cell semiconductor patterns SP may be formed through a deposition process. The deposition process for forming the cell gate insulating layer GI may use, for example, the ALD or CVD process. Next, the cell gate electrode GE covering the cell gate insulating layer GI may be formed. For example, the CVD process may be performed to remove a portion of the interlayer insulating layer 132 through the selective etching process, thereby forming the cell gate electrode GE that fills the remaining space. Accordingly, the cell transistor CTR including the cell gate electrode GE and the cell semiconductor pattern SP may be formed.

The cell gate electrode GE may have a line shape extending in the second direction DR2. The cell gate electrode GE may surround the plurality of cell semiconductor patterns SP disposed in the second direction DR2. The cell gate electrode GE may be separated from the cell gate electrode GE by the cell gate insulating layer GI. The cell gate electrode GE may be disposed in the word line region WR of FIG. 42.

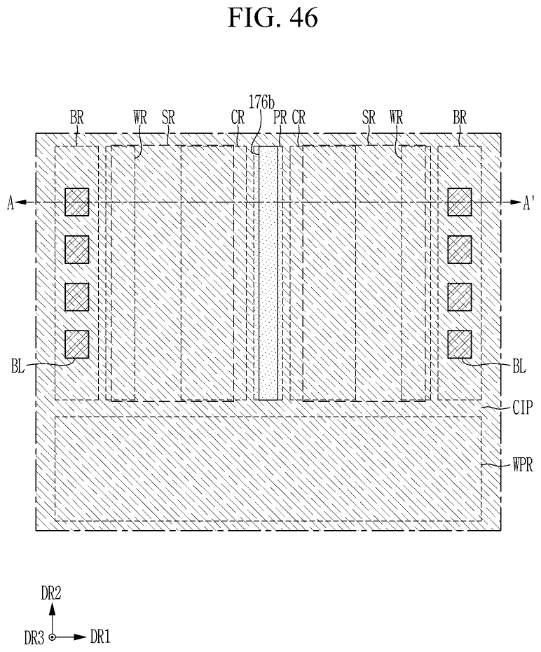

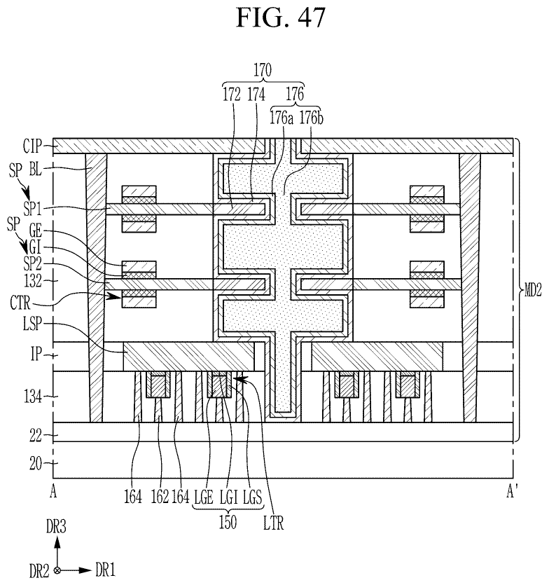

Referring to FIG. 46 and FIG. 47, the bit line BL penetrating the interlayer insulating layer 132, the insulating pattern IP, and the upper insulating layer 134 may be formed.

For example, the fourth trench penetrating the interlayer insulating layer 132, the insulating pattern IP, and the upper insulating layer 134 may be formed. The fourth trench may be formed through a process of etching the interlayer insulating layer 132, the insulating pattern IP, and the upper insulating layer 134 in the third direction DR3, and the etching process for forming the fourth trench may be performed up to the upper surface of the etch-stop layer 22. As the fourth trench is formed, one end of each of the plurality of cell semiconductor patterns SP may be exposed. For example, one end of each of the plurality of cell semiconductor patterns SP in the first direction DR1 may be exposed. The surface of each exposed end of the plurality of cell semiconductor patterns SP may be doped with impurities.

Next, a conductive material may be filled into the fourth trench to form the bit line BL. The bit line BL may contact one end of each of the plurality of cell semiconductor patterns SP. The bit line BL may have a pillar shape extending in the third direction DR3. The plurality of cell semiconductor patterns SP stacked in the third direction DR3 may be connected to a single bit line BL. The diameter of the bit line BL (for example, a width in the first direction DR1 may decrease as a distance from the upper surface of the etch-stop layer 22 decreases, which may correspond to the sidewall profile of the fourth trench.

The bit line BL may be formed in the bit line BL region of FIG. 46. In FIG. 46, the planar shape of the bit line BL is illustrated as being quadrangle, but is not limited thereto and may be variously changed to a circular shape, an elliptical shape, or another polygonal shape.

Next, a cover insulating layer covering the bit line BL and the interlayer insulating layer 132 may be formed. The process of forming the bit line BL and the process of forming the cover insulating layer may be changed in order. For example, the cover insulating layer covering the interlayer insulating layer 132 may be formed first, and then the bit line BL may be formed. In this case, the bit line BL may penetrate further the cover insulating layer.

Next, the cover insulating layer may be patterned to form the cover insulating pattern CIP. The cover insulating pattern CIP may include an opening. The fifth trench may be formed by performing an etching process using the cover insulating pattern CIP as an etching mask. The plurality of capacitors 170 may be formed through the fifth trench. The fifth trench may be formed through a process of etching the interlayer insulating layer 132, the insulating pattern IP, and the upper insulating layer 134 in the third direction DR3, and the etching process for forming the fifth trench may be performed up to the upper surface of the etch-stop layer 22. The bottom surface of the fifth trench may be defined by the upper surface of the etch-stop layer 22. The sidewall of the fifth trench may be defined by the side surface of the interlayer insulating layer 132, the side surface of each of the plurality of cell semiconductor patterns SP, the side surface of the insulating pattern IP, and the side surface of the upper insulating layer 134. As the fifth trench is formed, the plurality of cell semiconductor patterns SP may be exposed.

Next, a portion of each of the plurality of cell semiconductor patterns exposed through the fifth trench may be etched to form a plurality of first recesses. The first recess may be formed by etching the cell semiconductor pattern SP in the first direction DR1. As the first recess is formed, the other end of the cell semiconductor pattern SP may be exposed. For example, the other end of each of the plurality of cell semiconductor patterns SP in the first direction DR1 may be exposed. The first recess may be used to dope impurities onto the surface of the exposed other end of each of the plurality of cell semiconductor patterns SP.

Next, a conductive material may be filled in the plurality of first recesses to form the plurality of first electrodes 172. Each of the plurality of first electrodes 172 may be in contact with the other end of each of the plurality of cell semiconductor patterns SP. Each of the plurality of first electrodes 172 may be connected to each of the plurality of cell semiconductor patterns SP in the first direction DR1.

Next, a portion of the interlayer insulating layer 132 exposed through the fifth trench may be etched to form a plurality of second recesses. A portion of the plurality of second recesses may have side walls defined by surfaces of the plurality of first electrodes 172 facing in the third direction DR3, and bottom surfaces defined by side surfaces of the interlayer insulating layer 132. The other portion of the plurality of second recesses may have side walls defined by the upper surface of the first electrode 172, the upper surface of the logic semiconductor pattern LSP and the upper surface of the insulating pattern IP, and a bottom surface defined by the side surface of the interlayer insulating layer 132. The other portion of the plurality of second recesses may have side walls defined by the upper surface of the first electrode 172 and the lower surface of the cover insulating pattern CIP, and a bottom surface defined by the side surface of the interlayer insulating layer 132. Each of the plurality of second recesses may be formed by etching the interlayer insulating layer 132 disposed between the plurality of cell semiconductor patterns SP, between the top cell semiconductor pattern SP and the cover insulating pattern CIP, and between the bottom cell semiconductor pattern SP and the logic semiconductor pattern LSP in the first direction DR1.

Next, the dielectric layer 174 and the first conductive layer 176a covering the sidewalls and bottom surfaces of the plurality of second recesses and the sidewalls and bottom surface of the fifth trench may be formed. The dielectric layer 174 and the first conductive layer 176a may further cover the side surface of the opening of the cover insulating pattern CIP. The dielectric layer 174 may be formed first, and then the first conductive layer 176a may be formed on the dielectric layer 174. Accordingly, the dielectric layer 174 may be disposed between the plurality of first electrodes 172 and the first conductive layer 176a.

Each of the dielectric layer 174 and the first conductive layer 176a may have a conformal shape. Each of the dielectric layer 174 and the first conductive layer 176a may have the same shape as the surface profile of the fifth trench and the plurality of second recesses.

Next, the remaining space of the plurality of second recesses and the remaining space of the fifth trench may be filled with a conductive material to form the second conductive layer 176b. For example, the first conductive layer 176a and the second conductive layer 176b may include different conductive materials. The first conductive layer 176a may include the same conductive material as the first electrode 172, and the second conductive layer 176b may include a different conductive material than the first electrode 172. For example, the first conductive layer 176a may include a metal (for example, titanium nitride), and the second conductive layer 176b may include a doped semiconductor material (for example, doped silicon germanium).

The first conductive layer 176a and the second conductive layer 176b may form the second electrode 176. According to an embodiment, each of the plurality of first electrodes 172 is spaced apart from each other, and each of the dielectric layer 174, the first conductive layer 176a, and the second conductive layer 176b may be formed integrally. The second electrode 176 may be spaced apart from the plurality of first electrodes 172 by the dielectric layer 174. The plurality of first electrodes 172, the dielectric layer 174, and the second electrode 176 may form the plurality of capacitors 170. Each of the plurality of capacitors 170 may be defined by the first electrode 172, the second electrode 176 surrounding the first electrode 172, and the dielectric layer 174 interposed between the first electrode 172 and the second electrode 176. The second electrode 176 may be disposed in the plate region PR of FIG. 46, and the plurality of capacitors 170 may be disposed in the capacitor region CR of FIG. 46.

The structure formed on the first carrier substrate 20 according to the above-described processes may be referred to as a second intermediate structure MD2 hereinafter.

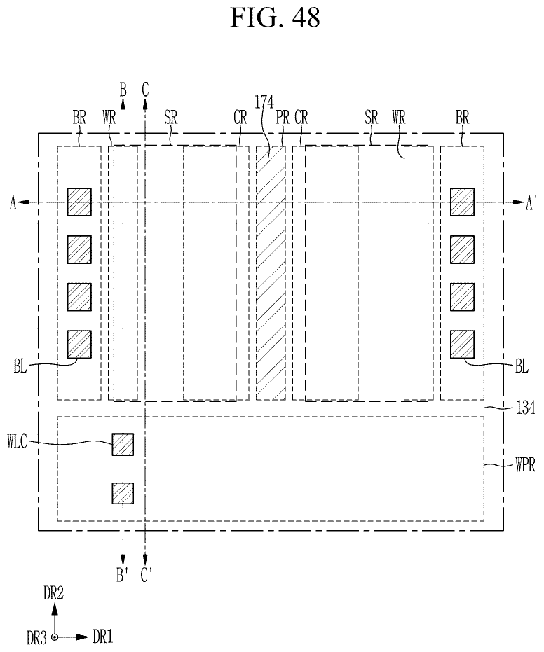

Referring to FIGS. 48 to 51, the second intermediate structure MD2 on the first carrier substrate 20 may be flipped and attached on the lower insulating layer 140 disposed on a second carrier substrate 30. Accordingly, the cover insulating pattern CIP may be disposed on the upper surface of the lower insulating layer 140. A portion of the dielectric layer 174 and a portion of the second electrode 176 disposed in the opening of the cover insulating pattern CIP may contact the upper surface of the lower insulating layer 140. As the second intermediate structure MD2 is flipped, the diameter (for example, a width in the first direction DR1) of the bit line BL may decrease as a distance from the upper surface of the lower insulating layer 140 decreases.

The plurality of cell semiconductor patterns SP may include the first cell semiconductor pattern SP1 and the second cell semiconductor pattern SP2 that are stacked in the third direction DR3. By flipping the second intermediate structure MD2, the first cell semiconductor pattern SP1 may be closer to the upper surface of the lower insulating layer 140 than the second cell semiconductor pattern SP2. According to an embodiment, the width of the first cell semiconductor pattern SP1 in the second direction DR2 may be shorter than the width of the second cell semiconductor pattern SP2 in the second direction DR2.

Next, the first carrier substrate 20 and the etch-stop layer 22 may be removed.

Next, the remaining portions 110P of the first layer 110 disposed on the same layer as each of the plurality of cell semiconductor patterns SP may be replaced with a conductive material to form the plurality of cell gate connection pads WLP connected to each of the plurality of cell gate electrodes GE. Each of the plurality of cell gate connection pads WLP may be connected to each of the plurality of cell gate electrodes GE in the second direction DR2. The plurality of cell gate connection pads WLP may be disposed in the word line pad region WPR of FIG. 48.

For example, the plurality of cell gate electrodes GE may include the first cell gate electrode GE1 surrounding the first cell semiconductor pattern SP1 and the second cell gate electrode GE2 surrounding the second cell semiconductor pattern SP2. The first cell gate insulating layer GI1 may be disposed between the first cell gate electrode GE1 and the first cell semiconductor pattern SP1, and the second cell gate insulating layer GI2 may be disposed between the second cell gate electrode GE2 and the second cell semiconductor pattern SP2. The plurality of cell gate connection pads WLP may include the first cell gate connection pad WLP1 connected to the first cell gate electrode GE1 and the second cell gate connection pad WLP2 connected to the second cell gate electrode GE2.

For example, the first cell semiconductor pattern SP1 may be closer to the upper surface of the lower insulating layer 140 than the second cell semiconductor pattern SP2. The first cell gate electrode GE1 surrounding the first cell semiconductor pattern SP1 may be closer to the upper surface of the lower insulating layer 140 than the second cell gate electrode GE2 surrounding the second cell semiconductor pattern SP2. The first cell gate connection pad WLP1 connected to the first cell gate electrode GE1 may be closer to the upper surface of the lower insulating layer 140 than the second cell gate connection pad WLP2 connected to the second cell gate electrode GE2.

The plurality of cell gate connection pads WLP may be longer in the second direction DR2 in which each of the plurality of cell gate electrodes GE extends as a distance from the upper surface of the lower insulating layer 140 decreases. For example, the first cell gate connection pad WLP1 may be longer in the second direction DR2 than the second cell gate connection pad WLP2. The plurality of cell gate connection pads WLP may have a stepped structure.

Next, the plurality of sixth trenches penetrating the upper insulating layer 134, the insulating pattern IP, and the interlayer insulating layer 132 may be formed. The plurality of sixth trenches may be formed through a process of etching the upper insulating layer 134, the insulating pattern IP, and the interlayer insulating layer 132 in the third direction DR3, and the etching process for forming the plurality of sixth trenches may use the cell gate connection pad WLP as an etch-stop layer.

Next, the plurality of sixth trenches may be filled with a conductive material to form the plurality of cell gate contacts WLC. Each of the plurality of cell gate contacts WLC may contact the upper surface of each of the plurality of cell gate connection pads WLP. Each of the plurality of cell gate connection pads WLP may be connected to each of the plurality of cell gate electrodes GE stacked in the third direction DR3. The cell gate contact WLC may have a pillar shape extending in the third direction DR3. The diameter of the cell gate contact WLC (for example, a width in the second direction DR2) may decrease as a distance from the upper surface of the cell gate connection pad WLP decreases, which may correspond to the sidewall profile of the sixth trench.

The cell gate contact WLC may be disposed in the word line pad region WPR of FIG. 48. In FIG. 48, the planar shape of the cell gate contact WLC is illustrated as being quadrangle, but is not limited thereto and may be variously changed to a circular shape, an elliptical shape, or another polygonal shape.

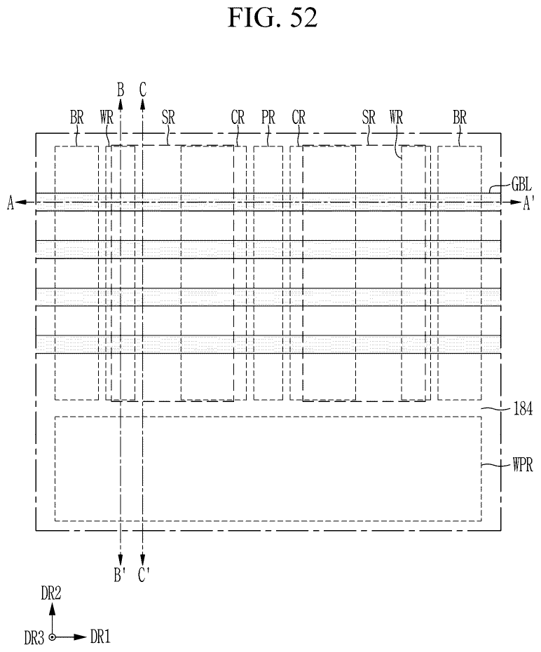

Referring to FIGS. 52 to 55, the wiring layer 180 and the global bit line GBL may be formed on the upper insulating layer 134. For example, the wiring insulating layer 184 may be formed on the upper insulating layer 134, and then a conductive material may be deposited after patterning the wiring insulating layer 184 to form the plurality of wirings 182, the plurality of vias 186, and the global bit line GBL. The plurality of wirings 182 may be formed of a plurality of layers, and the plurality of vias 186 may connect the plurality of wirings 182 disposed in different layers. The plurality of wirings 182 and the plurality of vias 186 may be connected to the global bit line GBL, the bit line BL, the cell gate contact WLC, the second electrode 176 of the plurality of capacitors 170, the logic gate contact 162, and the source/drain contact 164.

The two side surfaces and the bottom surface of the global bit line GBL may be surrounded by a wiring insulating layer 184, but is not necessarily limited thereto. For example, a wiring insulating layer 184 may be further disposed on the upper surface of the global bit line GBL. The plurality of wirings 182 surrounded by the wiring insulating layer 184 on the upper surface of the global bit line GBL and the plurality of vias 186 penetrating the wiring insulating layer 184 may be further disposed.

According to an embodiment, the wiring layer 180 may connect the global bit line GBL and the logic transistor LTR, and may connect the bit line BL and the logic transistor LTR. For example, the wiring layer 180 may connect the global bit line GBL to one of the pair of source/drain contacts 164 that are connected to a pair of source/drain regions of the logic transistor LTR, and may connect the bit line BL to the other of the pair of source/drain contacts 164. That is, the logic transistor LTR may be connected between the global bit line GBL and the bit line BL.

After completing the above-described processes, the second carrier substrate 30 may be removed.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. A method of manufacturing a semiconductor device, comprising:
forming an intermediate structure including a plurality of first layers;
forming a plurality of cell semiconductor patterns by patterning a subset of the plurality of first layers such that an adjacent layer that is adjacent to a first surface of the substrate remains unpatterned;
after flipping the intermediate structure on the substrate and attaching the intermediate structure on a lower insulating layer:
patterning the adjacent layer to form a logic semiconductor pattern;
forming a bit line connected to first ends of the plurality of cell semiconductor patterns; and
forming a plurality of capacitors, connected to second ends of the plurality of cell semiconductor patterns, between the logic semiconductor pattern and the lower insulating layer.

2. The method of claim 1, wherein the intermediate structure further includes a plurality of second layers alternating with the plurality of first layers, and wherein forming of the plurality of cell semiconductor patterns comprises:
removing a subset of the plurality of second layers except for a contact layer, of the plurality of second layers, that is in contact with the first surface of the substrate;
filling a space from which the subset of the plurality of second layers have been removed with an insulating material to form an interlayer insulating layer; and
forming a first trench penetrating the subset of the plurality of first layers in a direction perpendicular to the first surface of the substrate.

3. The method of claim 2, further comprising forming a plurality of cell gate electrodes surrounding each of the plurality of cell semiconductor patterns by:
forming a plurality of cell gate insulating layers surrounding each of the plurality of cell semiconductor patterns; and
forming the plurality of cell gate electrodes covering the plurality of cell gate insulating layers,
wherein each of the plurality of cell gate electrodes extends in a direction parallel to the first surface of the substrate.

4. The method of claim 3, wherein forming the logic semiconductor pattern comprises, after attaching the intermediate structure on the lower insulating layer:
removing the substrate and the contact layer;
forming a second trench penetrating the adjacent layer in a direction perpendicular to the upper surface of the lower insulating layer; and
filling the second trench with an insulating material to form an insulating pattern.

5. The method of claim 4, further comprising:
forming a logic gate electrode on the logic semiconductor pattern; and
after forming the logic gate electrode:
forming an upper insulating layer covering the logic gate electrode, the logic semiconductor pattern, and the insulating pattern; and
forming a logic gate contact penetrating the upper insulating layer and in contact with an upper surface of the logic gate electrode, and forming a pair of source/drain contacts penetrating the upper insulating layer and in contact with an upper surface of the logic semiconductor pattern disposed on both sides of the logic gate electrode.

6. The method of claim 5, wherein forming the bit line comprises:
forming a third trench penetrating the upper insulating layer, the insulating pattern, and the interlayer insulating layer; and
filling the third trench with a conductive material to form the bit line in contact with the first ends of the plurality of cell semiconductor patterns.

7. The method of claim 5, wherein forming the plurality of capacitors comprises:
forming a fourth trench penetrating the upper insulating layer, the insulating pattern, and the interlayer insulating layer;
etching a portion of each of the plurality of cell semiconductor patterns exposed through the fourth trench to form a plurality of first recesses;
filling a conductive material in the plurality of first recesses to form a plurality of first electrodes in contact with the second ends of the plurality of cell semiconductor patterns;
etching a portion of the interlayer insulating layer exposed through the fourth trench to form a plurality of second recesses;
forming a dielectric layer and a first conductive layer covering sidewalls and bottom surfaces of the plurality of second recesses and a sidewall and a bottom surface of the fourth trench; and
filling a remaining space of the plurality of second recesses and a remaining space of the fourth trench with a conductive material to form a second conductive layer,
wherein the first conductive layer and the second conductive layer are included in a second electrode spaced apart from the plurality of first electrodes by the dielectric layer.

8. The method of claim 5, further comprising, after forming the upper insulating layer:
replacing portions of the plurality of first layers that are disposed on a same layer as each of the plurality of cell semiconductor patterns with a conductive material to form a plurality of cell gate connection pads connected to each of the plurality of cell gate electrodes;
forming a plurality of fifth trenches penetrating the upper insulating layer, the insulating pattern, and the interlayer insulating layer; and
filling the plurality of fifth trenches with a conductive material to form a plurality of cell gate contacts in contact with the upper surface of each of the plurality of cell gate connection pads,
wherein the plurality of cell gate connection pads become longer in a direction in which each of the plurality of cell gate electrodes extends as a distance from the upper surface of the lower insulating layer decreases.

9. The method of claim 8, further comprising, after forming the bit line, the plurality of capacitors, and the plurality of cell gate contacts:
forming a wiring layer and a global bit line on the upper insulating layer,
wherein the wiring layer connects the global bit line to a first pair of source/drain contacts and connects the bit line to a second pair of source/drain contacts.

10. A method of manufacturing a semiconductor device, comprising:
forming a first intermediate structure including a plurality of first layers;
forming a logic semiconductor pattern by patterning a remote layer that is furthest from a first surface of the substrate among the plurality of first layers;
after flipping the first intermediate structure on the substrate and attaching the first intermediate structure on an etch-stop layer, forming a second intermediate structure by:
forming a plurality of cell semiconductor patterns by patterning a subset of the plurality of first layers;
forming a bit line connected to first ends of the plurality of cell semiconductor patterns;
forming a plurality of capacitors connected to second ends of the plurality of cell semiconductor patterns; and
attaching the second intermediate structure on a lower insulating layer, wherein the plurality of capacitors are disposed between the logic semiconductor pattern and the lower insulating layer.

11. The method of claim 10, wherein forming the logic semiconductor pattern comprises:
forming a first trench penetrating the remote layer in a direction perpendicular to the first surface of the substrate; and
filling the first trench with an insulating material to form an insulating pattern.

12. The method of claim 11, further comprising:
forming a logic gate electrode on the logic semiconductor pattern; and
after forming the logic gate electrode:
forming an upper insulating layer covering the logic gate electrode, the logic semiconductor pattern, and the insulating pattern; and
forming a logic gate contact penetrating the upper insulating layer and in contact with an upper surface of the logic gate electrode, and forming a pair of source/drain contacts penetrating the upper insulating layer and in contact with an upper surface of the logic semiconductor pattern disposed on both sides of the logic gate electrode.

13. The method of claim 12, wherein the first intermediate further includes a plurality of second layers alternating with the plurality of first layers, and wherein forming the plurality of cell semiconductor patterns comprises:
after attaching the first intermediate structure on the etch-stop layer:
removing the substrate;
removing the plurality of second layers;
filling a space from which the plurality of second layers have been removed with an insulating material to form an interlayer insulating layer; and
forming a second trench penetrating the subset of the plurality of first layers in a direction perpendicular to the first surface of the first carrier substrate.

14. The method of claim 13, further comprising forming a plurality of cell gate electrodes surrounding each of the plurality of cell semiconductor patterns, wherein forming the plurality of cell gate electrodes comprises:
forming a plurality of cell gate insulating layers surrounding each of the plurality of cell semiconductor patterns; and
forming the plurality of cell gate electrodes covering the plurality of cell gate insulating layers,
wherein each of the plurality of cell gate electrodes extends in a direction parallel to the first surface of the first carrier substrate.

15. The method of claim 14, wherein forming the bit line comprises:
forming a third trench penetrating the interlayer insulating layer, the insulating pattern, and the upper insulating layer; and
filling the third trench with a conductive material to form the bit line in contact with the first ends of the plurality of cell semiconductor patterns.

16. The method of claim 15, wherein forming the plurality of capacitors comprises:
forming an insulating pattern on the bit line and the interlayer insulating layer;
forming a fourth trench penetrating the interlayer insulating layer, the insulating pattern, and the upper insulating layer using the insulating pattern as an etching mask;
etching a portion of each of the plurality of cell semiconductor patterns exposed through the fourth trench to form a plurality of first recesses;
filling the plurality of first recesses with a conductive material to form a plurality of first electrodes in contact with the second ends of the plurality of cell semiconductor patterns;
etching a portion of the interlayer insulating layer exposed through the fourth trench to form a plurality of second recesses;
forming a dielectric layer and a first conductive layer covering sidewalls and bottom surfaces of the plurality of second recesses and a sidewall and a bottom surface of the fourth trench; and
filling a remaining space of the plurality of second recesses and a remaining space of the fourth trench with a conductive material to form a second conductive layer,
wherein the first conductive layer and the second conductive layer are included in a second electrode spaced apart from the plurality of first electrodes by the dielectric layer.

17. The method of claim 16, further comprising, after attaching the second intermediate structure on the lower insulating layer:
removing the etch-stop layer;
replacing portions of the plurality of first layers that are disposed on a same layer as each of the plurality of cell semiconductor patterns with a conductive material to form a plurality of cell gate connection pads connected to each of the plurality of cell gate electrodes;
forming a plurality of fifth trenches penetrating the upper insulating layer, the insulating pattern, and the interlayer insulating layer; and
filling the plurality of fifth trenches with a conductive material to form a plurality of cell gate contacts in contact with the upper surface of each of the plurality of cell gate connection pads,
wherein the plurality of cell gate connection pads become longer in a direction in which each of the plurality of cell gate electrodes extends as a distance from the upper surface of the lower insulating layer decreases.

18. The method of claim 17, further comprising, after forming the bit line, the plurality of capacitors, and the plurality of cell gate contacts:
forming a wiring layer and a global bit line on the upper insulating layer,
wherein the wiring layer connects the global bit line to a first pair of source/drain contacts and connects the bit line to a second pair of source/drain contacts.

19. A method of manufacturing a semiconductor device, comprising:
forming an intermediate structure including a plurality of first layers;
forming a plurality of cell semiconductor patterns by patterning a subset of the plurality of first layers such that an adjacent layer that is adjacent to a first surface of the substrate remains unpatterned;
after flipping the intermediate structure on the substrate and attaching the intermediate structure on a lower insulating layer:
patterning the adjacent layer to form a logic semiconductor pattern;
forming a bit line connected to first ends of the plurality of cell semiconductor patterns along a first direction; and
forming a plurality of capacitors, connected to second ends of the plurality of cell semiconductor patterns along the first direction, overlapping with the logic semiconductor pattern in a direction perpendicular to an upper surface of the lower insulating layer.

20. The method of claim 19, wherein
forming a plurality of cell semiconductor patterns comprises:
forming an opening penetrating the subset of the plurality of first layers, and
filling the opening with an insulating material to form an interlayer insulating layer,
wherein the width of the opening becomes narrower as it approaches the upper surface of the substrate,
wherein the plurality of cell semiconductor patterns include a first cell semiconductor pattern and a second cell semiconductor pattern, the first cell semiconductor pattern is closer to an upper surface of a lower insulating layer than the second cell semiconductor pattern, and
wherein a width of the first cell semiconductor pattern in a second direction orthogonal to the first direction is shorter than a width of the second cell semiconductor pattern in the second direction.
